(19) United States
(12) Patent Application Publication
(10) Pub. No.: US 2025/0287675 A1
(43) Pub. Date: Sep. 11, 2025

(54) MOLYBDENUM HALIDES IN MEMORY APPLICATIONS

(71) Applicant: Lam Research Corporation, Fremont, CA (US)

(72) Inventors: Naveen Kumar MAHENDERKAR, San Jose, CA (US); Yao-Tsung HSIEH, San Jose, CA (US); Chiukin Steven LAI, Sunnyvale, CA (US); Lawrence SCHLOSS, Palo Alto, CA (US); Sanjay GOPINATH, Fremont, CA (US)

(21) Appl. No.: 18/859,971

(22) PCT Filed: Apr. 25, 2023
(86) PCT No.: PCT/US2023/019795

§ 371 Date: Oct. 24, 2024

Related U.S. Application Data
(60) Provisional application No. 63/364,251, filed on May 5, 2022.
(60) Provisional application No. 63/364,795, filed on May 16, 2022.

(51) Int. Cl. H10D 64/66; H10B 41/10; H10B 41/20; H10B 41/35; H10B 43/10; H10B 43/20; H10B 43/35; H10D 64/01

(52) U.S. Cl. CPC H10D 64/665; H10B 41/10; H10B 41/20; H10B 41/35; H10B 43/10; H10B 43/20; H10B 43/35; H10D 64/037

(57) ABSTRACT

Provided are processes of filling features with method. The processes include deposition, etch, and clean operations using a molybdenum chloride (MoClₓ) compound. The MoClₓ compound may be controlled to selectively deposit on metal nitride features compared to dielectric, form plugs and crystals on dielectric materials, and perform a net etch of materials within the feature. Also provided are in-situ clean processes in which the MoClₓ compound is used to remove oxidation from underlying surfaces prior to deposition. Subsequent deposition using the MoClₓ precursor may deposit an initial layer and/or fill a feature.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Deposition of materials, including tungsten-containing materials, is an integral part of many semiconductor fabrication processes. These materials may be used for horizontal interconnects, vias between adjacent metal layers, contacts between metal layers and devices, and as lines in memory devices. In an example of deposition, a tungsten (W) layer may be deposited on a titanium nitride (TiN) barrier layer to form a TiN/W bilayer by a CVD process using tungsten hexafluoride (WF₆). However, as devices shrink and more complex patterning schemes are utilized in the industry, deposition of thin tungsten films becomes a challenge. The continued decrease in feature size and film thickness brings various challenges to TiN/W film stacks. These include high resistivity for thinner films and deterioration of TiN barrier properties. Deposition in complex high aspect ratio structures such as 3D NAND structures is particularly challenging.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

One aspect of the disclosure relates to a method, including: (a) providing a substrate comprising a feature comprising an opening and sidewalls, wherein a metal nitride layer lines the sidewalls of the feature; (b) at least partially etching the metal nitride layer along the sidewalls of the feature using a molybdenum-containing halide compound to leave a first portion of the metal nitride layer in the feature; and (c) after at least partially etching the metal nitride layer, selectively depositing molybdenum on the first portion of the metal nitride layer in the feature by reacting the molybdenum-containing halide compound with a first reactant.

In some embodiments, wherein (b) includes removing metal nitride from a portion of the sidewalls to expose the portion of the sidewalls of the feature

In some embodiments, where the feature has a feature bottom, and further comprising (d) after (c), at least partially etching the first portion of the metal nitride layer and molybdenum using the molybdenum-containing halide compound to leave a second portion of the metal nitride layer and remaining molybdenum on the feature bottom.

In some embodiments, further including, (e) filling the feature with molybdenum.

In some embodiments, where the molybdenum-containing halide compound is a molybdenum chloride compound

In some embodiments, where the molybdenum-containing halide compound is molybdenum pentachloride.

In some such embodiments, where (e) includes reacting a second molybdenum-containing halide compound with a second reactant.

In some such embodiments, where (e) includes reacting a molybdenum-containing oxyhalide precursor with a second reactant.

In some embodiments, where the metal nitride layer conformally lines the feature.

In some embodiments, where (b) further comprises reacting the molybdenum-containing halide compound with the first reactant to deposit molybdenum in the feature during the etch.

In some embodiments, where the reactant is a hydrogen-containing reactant.

In some embodiments, where the first reactant is hydrogen (H₂).

In some embodiments, where (b) is performed at a first substrate temperature, (c) is performed at a substrate second temperature; and the second temperature is higher than the first temperature.

One aspect of the disclosure relates to a method, including: (a) providing a substrate comprising a feature comprising an opening, a closed end, and dielectric sidewalls; (b) forming a molybdenum plug on the closed end of the feature by reacting a molybdenum-containing halide precursor with a reactant; and (c) selectively depositing molybdenum on the molybdenum plug by reacting the molybdenum-containing halide precursor with the reactant.

In some embodiments, where the sidewalls are sloped and meet at the closed end of the feature.

In some embodiments, further including (d) after (c), filling the feature with molybdenum.

In some embodiments, where (d) includes reacting a second molybdenum-containing halide compound with a second reactant.

In some embodiments, where (d) includes reacting a molybdenum-containing oxyhalide compound with a second reactant.

In some embodiments, where the molybdenum-containing halide compound is a molybdenum chloride compound.

In some embodiments where the molybdenum-containing halide compound is molybdenum pentachloride.

In some embodiments, where the first reactant is a hydrogen-containing reactant.

In some embodiments, where the first reactant is hydrogen (H₂).

In some embodiments, where the substrate temperature is below 450° C. at (b).

One aspect of the disclosure relates to a method, including: (a) providing a substrate comprising a feature with a metal nitride plug; and (b) selectively depositing molybdenum on the metal nitride plug in the feature by reacting a molybdenum-containing halide compound and a reactant.

In some embodiments, further including between (a) and (b), cleaning the feature using the molybdenum-containing halide compound.

In some embodiments, further including (c) after (b), filling the feature with molybdenum.

In some embodiments, where the molybdenum-containing halide compound is a molybdenum chloride compound.

In some embodiments, where the molybdenum-containing halide compound is molybdenum pentachloride.

In some embodiments, where the first reactant is a hydrogen-containing reactant.

In some embodiments, where the first reactant is hydrogen (H₂).

In some embodiments, where filling the feature with molybdenum includes reacting a second molybdenum-containing halide precursor with a second reactant.

In some embodiments, where filling the feature with molybdenum includes reacting a molybdenum-containing oxyhalide precursor with a reactant.

### BRIEF DESCRIPTION OF DRAWINGS

FIGS. 1A and 1B are schematic examples of material stacks that include molybdenum (Mo) according to various embodiments.

FIGS. 2A-2L are schematic examples of various structures into which molybdenum may be deposited in accordance with disclosed embodiments.

FIGS. 3-7 are flow diagrams showing certain operations in methods according to various embodiments.

FIGS. 8A-10C are schematic diagrams showing cross-sectional depictions of features during fill processes according to various embodiments.

FIG. 11 is a flow diagram showing a method to fill a feature by forming a molybdenum plug according to various embodiments.

FIGS. 12A-12C are schematic diagrams showing cross-sectional depictions of features filled using a molybdenum plug without a metal nitride layer according to various embodiments.

FIG. 13 illustrates a sequence to reduce resistivity according to various embodiments.

FIG. 14A is an illustration of an inhibitor non-conformally treating a feature according to various embodiments.

FIG. 14B is an illustration of a feature after a deposition, etch, deposition sequence according to various embodiments.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Provided herein are methods of filling features with molybdenum (referred to herein as Mo) that may be used for logic and memory applications. Molybdenum offers several benefits over other metals such as cobalt (Co), ruthenium (Ru), and tungsten (W). (i) barrier-less and liner-less molybdenum film deposition is more feasible on oxide and nitride as compared to Co, Ru, and W, (ii) molybdenum resistivity scaling is better than W, (iii) molybdenum intermixing with underlying Co is not expected compared to Ru intermixing with Co at less than 450° C., and (iv) there is relatively easy molybdenum integration into current W schemes compared to Co and Ru.

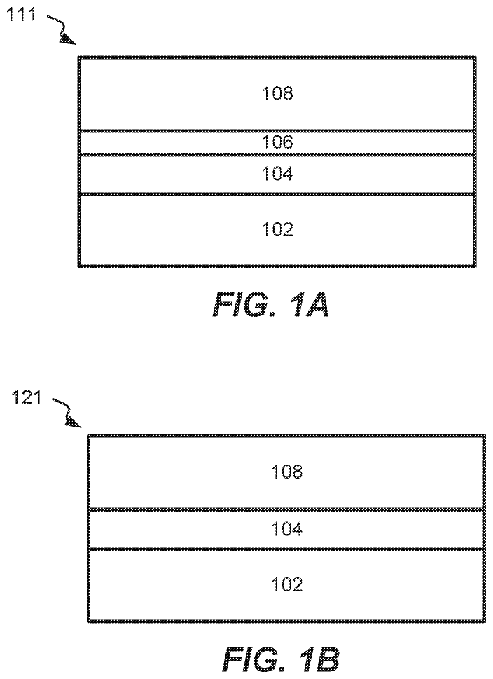

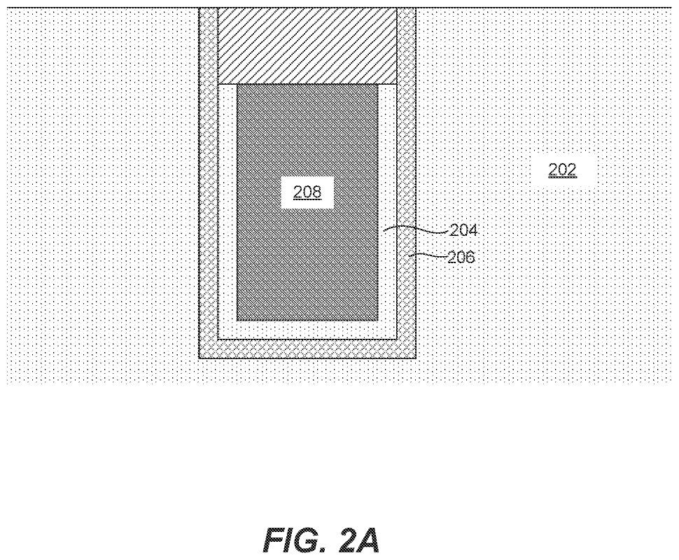

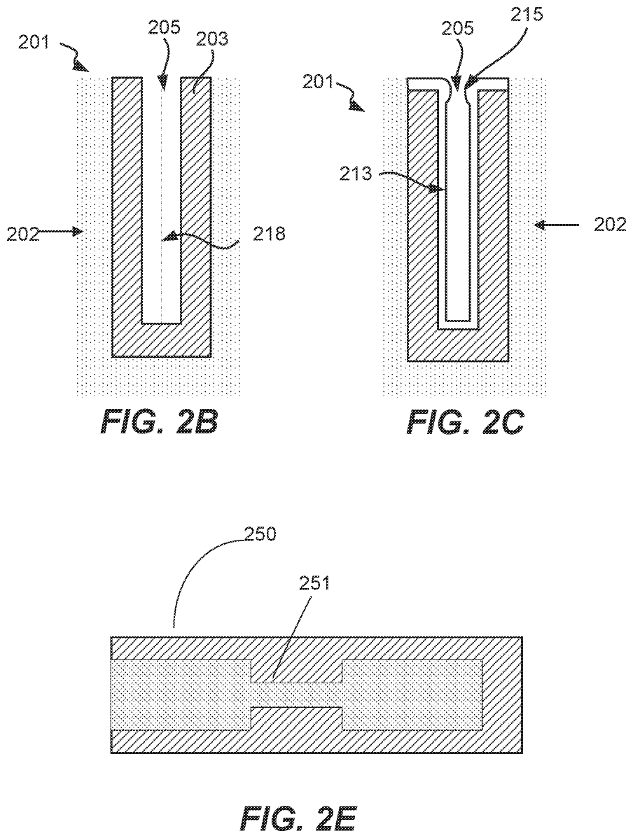

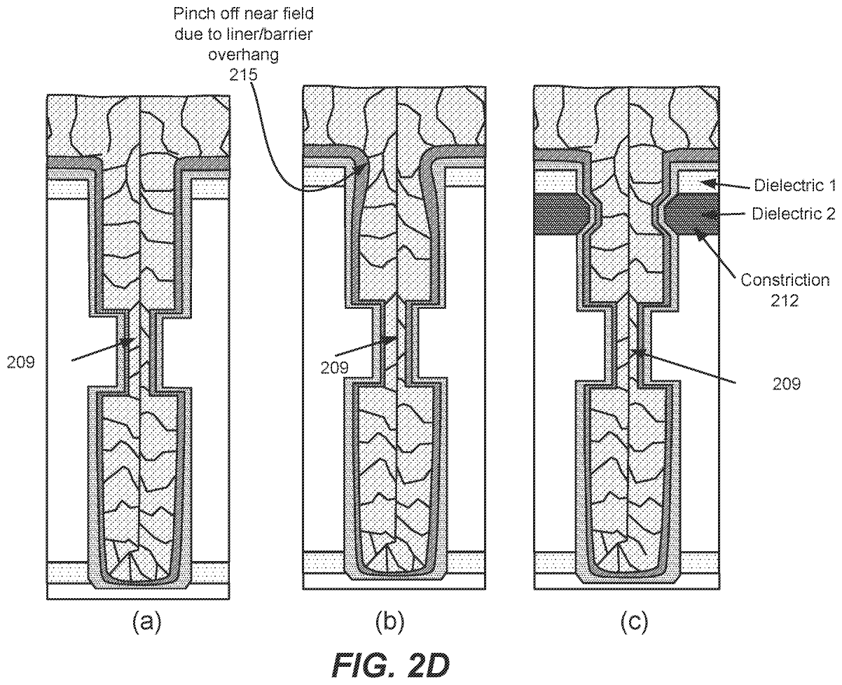

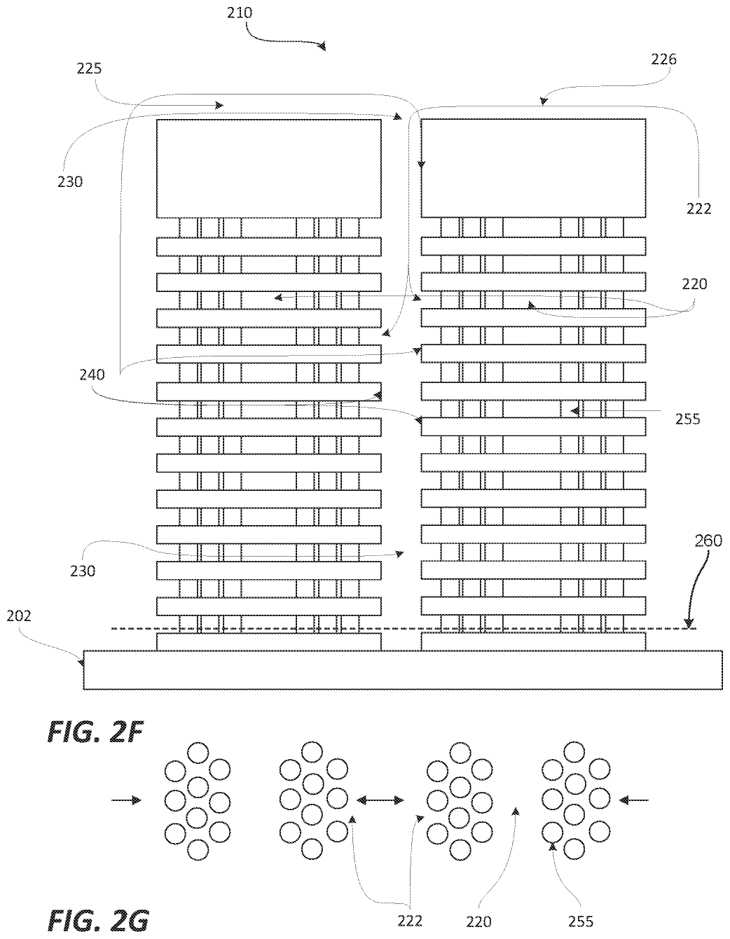

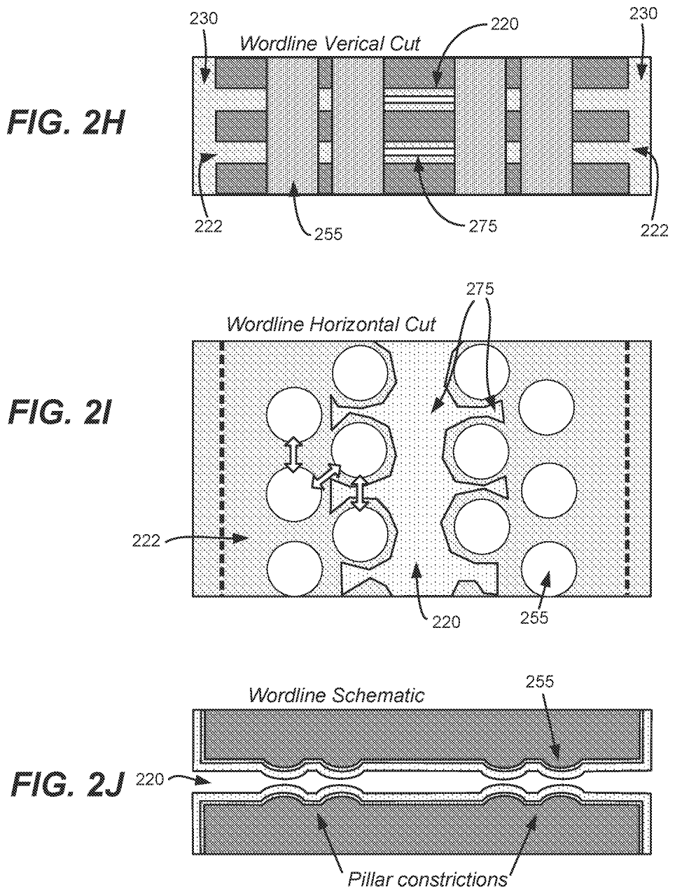

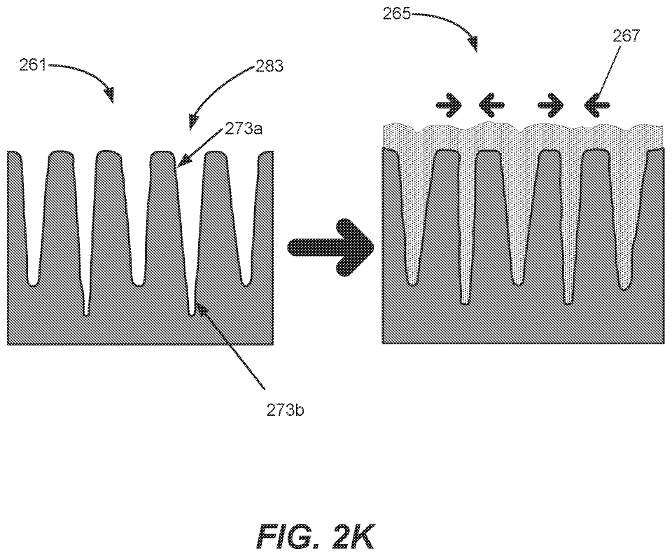

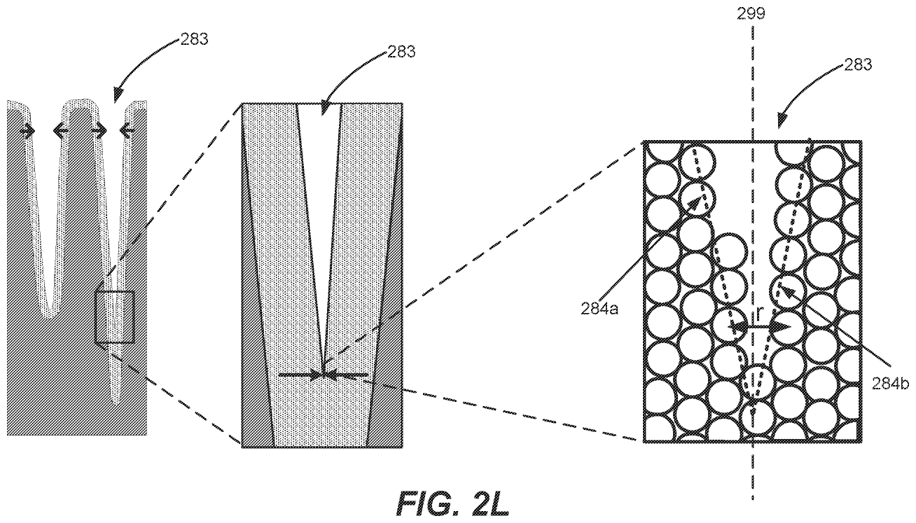

FIGS. 1A and 1B are schematic examples of material stacks that include molybdenum according to various embodiments. FIGS. 1A and 1B illustrate the order of materials in examples of particular stacks and may be used with any appropriate architecture and application, as described further below with respect to FIGS. 2A-2J. FIG. 1A shows a first material stack 111 featuring a substrate 102 and a molybdenum layer 108 deposited thereon. The substrate 102 may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. In some embodiments, the substrate 102 may be or include silicon germanium (SiGe). The methods may also be applied to form metallization stack structures on other substrates, such as glass, plastic, and the like.

The stack 111 has a dielectric layer 104 on the substrate 102. The dielectric layer 104 may be deposited directly on a semiconductor surface (e.g., a Si or SiGe surface) of the substrate 102, or there may be any number of intervening layers. For example, the substrate 102 may include any number of layers deposited in various arrangements on a semiconductor surface.

Examples of dielectric layers include doped and undoped silicon oxide, silicon nitride, and aluminum oxide layers, with specific examples including doped or undoped layers of SiO₂ and Al₂O₃. The stack 111 has a layer 106 disposed between the molybdenum layer 108 and the dielectric layer 104. The layer 106 may be a diffusion barrier and/or an adhesion layer, for example. A diffusion barrier is a layer that prevents diffusion of species between layers. An adhesion layer is a layer that promotes adhesion of a layer to an underlying layer. Examples of diffusion barrier and adhesion layers include titanium nitride (TiN), titanium/titanium nitride (Ti/TiN), tungsten (W), tungsten nitride (WN), and tungsten carbon nitride (WCN). The molybdenum layer 108 is the main conductor of the structure. In some embodiments, the molybdenum layer 108 may include multiple bulk layers deposited at different conditions. The molybdenum layer 108 may or may not include a molybdenum nucleation layer. In the depicted example of FIG. 1A, the molybdenum layer 108 is deposited directly on the layer 106. In other embodiments (not depicted), the molybdenum layer 108 may be deposited on a separate layer such as a growth initiation layer that includes another material, such as a tungsten (W) or W-containing growth initiation layer The growth initiation layer may be used to facilitate nucleation and growth of the molybdenum layer 108.

FIG. 1B shows another example of a stack 121. In this example, the stack 121 includes the substrate 102, dielectric layer 104, with molybdenum layer 108 deposited directly on the dielectric layer 104, without an intervening diffusion barrier or adhesion layer. The molybdenum layer 108 is as described with respect to FIG. 1A. By using molybdenum as the main conductor, low resistivity thin films can be obtained. Examples of low resistivity thin films include films with resistivity less than 40 uOhm-cm at 60 angstroms thickness and less than 15 uOhm-cm at 200 angstroms thickness.

In some embodiments, a stack (not shown) may include the substrate, a conductive layer, and a molybdenum layer deposited onto the conductive layer. As used herein, a conductive layer is a layer having a conductivity of at least 10⁴ Ω⁻¹cm⁻¹ at room temperature. Examples include molybdenum on a metal layer (e.g., W). In these embodiments, there is no dielectric layer between the molybdenum layer and the conductive layer. Similarly, the stack may include molybdenum deposited directly on a metal compound layer. Examples include molybdenum on a metal nitride layer (e.g., TiN, WN, or MoN). In still some other embodiments of a stack (not shown), the stack may include a substrate and a molybdenum layer deposited directly on the substrate, including directly on a semiconducting surface, on a dielectric surface, or on a conductive surface. FIGS. 1A and 1B illustrate examples of the order of materials in a particular stack and may be used with any appropriate architecture and application, as described further below with respect to FIGS. 2A-2J.

The methods described herein are performed on a substrate that may be housed in a chamber. The substrate may be a silicon or other semiconductor wafer, including wafers having one or more layers of material, such as dielectric, conducting, or semiconducting material deposited thereon. The methods are not limited to semiconductor substrates and may be performed to fill any feature with molybdenum.

Substrates may have features such as vias or contact holes, which may be characterized by one or more narrow and/or re-entrant openings, constrictions within the feature, and high aspect ratios. A feature may be formed in one or more of the above-described stacks or layers within a stack. For example, the feature may be formed at least partially in a dielectric layer. In some embodiments, a feature may have an aspect ratio of at least about 2:1, at least about 4.1, at least about 6:1, at least about 10:1, at least about 25:1, or higher. One example of a feature is a hole or via in a semiconductor substrate or a layer on the substrate.

FIG. 2A depicts a schematic example of a DRAM architecture, including a molybdenum (Mo) buried wordline (bWL) 208 in a silicon substrate 202. The molybdenum bWL is formed in a trench etched in the silicon substrate 202. Lining the trench is a conformal barrier layer 206 and an insulating layer 204. The conformal barrier layer 206 is disposed between the insulating layer 204 and the silicon substrate 202. In this example, the insulating layer 204 may be a gate oxide layer formed from a high-k dielectric material such as a silicon oxide or silicon nitride material. In some embodiments disclosed herein, the conformal barrier layer 206 is TiN or a tungsten-containing layer. In embodiments in which TiN is used as a conformal barrier layer, a conformal tungsten-containing growth initiation layer (not shown) may be present between the conformal barrier layer 206 and the molybdenum bWL 208. Alternatively, the molybdenum bWL 208 may be deposited directly on a TiN or other diffusion barrier. In some embodiments, one or both of layers 204 and 206 is not present.

The bWL structure shown in FIG. 2A is one example of an architecture that includes a molybdenum fill layer. During fabrication of the bWL, molybdenum is deposited into a feature that may be defined by an etched recess in the silicon substrate 202 that is conformally lined with layers 206 and 204, if present.

FIGS. 2B-2H are additional schematic examples of various structures into which molybdenum may be deposited in accordance with disclosed embodiments FIG. 2B shows an example of a cross-sectional depiction of a vertical feature 201 to be filled with Mo. The feature can include a feature hole 205 in a silicon substrate 202. The feature hole 205 may have an under-layer 203 lining the sidewall or interior of the feature hole 205 and may form the interior surfaces. The feature hole 205 or other feature may have a dimension near the opening, e.g., an opening diameter or line width of between about 10 nm to 500 nm, for example, between about 25 nm and about 300 nm. The feature hole 205 can be referred to as an unfilled feature or simply a feature. The vertical feature 201, and any feature, may be characterized in part by an axis 218 that extends through the length of the feature, with vertically-oriented features having vertical axes and horizontally-oriented features having horizontal axes. The under-layer 213 can be, for example, a diffusion barrier layer, an adhesion layer, a nucleation layer, a combination of thereof, or any other applicable material. Non-limiting examples of under-layers can include dielectric layers and conducting layers. Examples of dielectric materials include oxides, such as silicon oxide (SiO₂) and aluminum oxide (Al₂O₃); nitrides, such as silicon nitride (SiN); carbides, such as nitrogen-doped silicon carbide (NDC) and oxygen-doped silicon carbide (ODC), and low k dielectrics, such as carbon-doped SiO₂. In particular implementations an under-layer can be one or more of titanium, titanium nitride, tungsten nitride, titanium aluminide, tungsten, and molybdenum. In some embodiments, the under-layer is tungsten-free. In some embodiments, the under-layer is molybdenum-free.

In some embodiments, features are wordline features in a 3D NAND structure. For example, a substrate may include a wordline structure having an arbitrary number of wordlines (e.g., 50 to 150) with vertical channels at least 200 Å deep. Examples of wordline features are described further below. Another example of a feature is a trench in a substrate or layer. Features may be of any depth. In various embodiments, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers.

FIG. 2C shows an example of a vertical feature 201 that has a re-entrant profile. A re-entrant profile is a profile that narrows from a bottom, closed-end, or interior of the feature to the feature opening. According to various implementations, the profile may narrow gradually and/or include an overhang at the feature opening FIG. 2C shows an example of the latter, with an under-layer 213 lining the sidewall or interior surfaces of the feature hole 105. Similar to FIG. 2B, the under-layer 213 can be a diffusion barrier layer, an adhesion layer, a nucleation layer, a combination of thereof, or any other applicable material. Non-limiting examples of under-layers can include dielectric layers and conducting layers. The under-layer 213 forms an overhang 215 such that the under-layer 213 is thicker near the opening of the vertical feature 201 than inside the vertical feature 201.

In some implementations, features having one or more constrictions within the feature may be filled. FIG. 2D shows examples of views of various filled features having constrictions. Each of the examples (a), (b), and (c) in FIG. 2D includes a constriction 209 at a midpoint within the feature. The constriction 209 can be, for example, between about 15 nm-20 nm wide. Constrictions can cause pinch off during deposition of molybdenum in the feature using conventional techniques, with deposited metal blocking further deposition past the constriction before that portion of the feature is filled, resulting in voids in the feature. Example (b) further includes an overhang 215 (such as, a liner/barrier overhand) at the feature opening. Such an overhang could also be a potential pinch-off point. Example (c) includes a constriction 212 further away from the field region than the overhang 215 in example (b).

Horizontal features, such as in 3-D memory structures, can also be filled. FIG. 2E shows an example of a horizontal feature 250 that includes a constriction 251. For example, horizontal feature 250 may be a word line in a 3-D NAND (also referred to as vertical NAND or VNAND) structure. In some implementations, the constrictions can be due to the presence of pillars in a 3D NAND or other structure. FIG. 2F presents a cross-sectional side view of a 3-D NAND structure 210 (formed on a silicon substrate 202) having 3-D NAND stacks (left 225 and right 226), central vertical structure 230, and a plurality of stacked horizontal wordline features 220 with openings 222 on opposite sidewalls 240 of central vertical structure 230. Note that FIG. 2F displays two “stacks” of the exhibited 3-D NAND structure 210, which together form the “trench-like” central vertical structure 230. However, in certain embodiments, there may be more than two “stacks” arranged in sequence and running spatially parallel to one another, the gap between each adjacent pair of “stacks” forming a central vertical structure 230, like that explicitly illustrated in FIG. 2F. In this embodiment, the horizontal wordline features 220 are 3-D memory wordline features that are fluidically accessible from the central vertical structure 230 through the openings 222. Although not explicitly indicated in the figure, the horizontal wordline features 220 present in both the 3-D NAND stacks 225 and 226 shown in FIG. 2F (i.e., the left 3-D NAND stack 225 and the right 3-D NAND stack 226) are also accessible from the other sides of the stacks (far left and far right, respectively) through similar vertical structures formed by additional 3-D NAND stacks (to the far left and far right, but not shown). Each 3-D NAND stack 225, 226 contains a stack of wordline features that are fluidically accessible from both sides of the 3-D NAND stack through a central vertical structure 230. In the particular example schematically illustrated in FIG. 2F, each 3-D NAND stack contains 6 pairs of stacked wordlines. However a 3-D NAND memory layout may contain any number of vertically stacked pairs of wordlines.

The wordline features in a 3-D NAND stack can be formed by depositing an alternating stack of silicon oxide and silicon nitride layers, and then selectively removing the nitride layers leaving a stack of oxides layers having gaps between them. These gaps are the wordline features. Any number of wordlines may be vertically stacked in such a 3-D NAND structure so long as there is a technique for forming them available, as well as a technique available to successfully accomplish (substantially) void-free fills of the vertical features. Thus, for example, a VNAND stack may include between 2 and 512 horizontal wordline features, between 2 and 256 horizontal wordline features, between 8 and 128 horizontal wordline features, or between 16 and 64 horizontal wordline features, and so forth (the listed ranges understood to include the recited endpoints).

FIG. 2G presents a cross-sectional top-down view of the same 3-D NAND structure 210 shown in the side view in FIG. 2F with the cross-section taken through the horizontal section 260 as indicated by the dashed horizontal line in FIG. 2F. The cross-section of FIG. 2G illustrates several rows of pillars 255, which are shown in FIG. 1F to run vertically from the base of the substrate 202 to the top of the 3-D NAND structure 210. In some embodiments, the pillars 255 are formed from a polysilicon material and are structurally and functionally significant to the 3-D NAND structure 210. In some embodiments, such polysilicon pillars may serve as gate electrodes for stacked memory cells formed within the pillars. The top-view of FIG. 2G illustrates that the pillars 255 form constrictions in the openings 222 to wordline features 220. Fluidic accessibility of wordline features 220 from the central vertical structure 230 via openings 222 (as indicated by the arrows in FIG. 2G) is inhibited by pillars 255. In some embodiments, the size of the horizontal gap between adjacent polysilicon pillars is between about 1 and 20 nm. This reduction in fluidic accessibility increases the difficulty of uniformly filling wordline features 120 with material. The structure of wordline features 220 and the challenge of uniformly filling them with molybdenum material due to the presence of pillars 255 is further illustrated in FIGS. 2H, 2I, and 2J.

FIG. 2H exhibits a vertical cut through a 3-D NAND structure similar to that shown in FIG. 2F, but here focused on a single pair of wordline features 220 and additionally schematically illustrating a fill process which resulted in the formation of a void 275 in the filled wordline features 220. FIG. 1I also schematically illustrates void 175, but in this figure illustrated via a horizontal cut through pillars 155, similar to the horizontal cut exhibited in FIG. 2G. FIG. 2J illustrates the accumulation of molybdenum material around the constriction-forming pillars 255, the accumulation resulting in the pinch-off of openings 222, so that no additional molybdenum material can be deposited in the region of voids 275. Apparent from FIGS. 2H and 2I is that void-free molybdenum fill relies on migration of sufficient quantities of deposition precursor down through central vertical structure 230, through openings 222, past the constricting pillars 255, and into the furthest reaches of wordline features 220, prior to the accumulated deposition of molybdenum around pillars 255 causing a pinch-off of the openings 222 and preventing further precursor migration into wordline features 220. Similarly, FIG. 2J exhibits a single wordline feature 220 viewed cross-sectionally from above and illustrates how a generally conformal deposition of molybdenum material begins to pinch-off the interior of wordline feature 220 due to the fact that the significant width of pillars 255 acts to partially block, and/or narrow, and/or constrict what would otherwise be an open path through wordline feature 220. (It should be noted that the example in FIG. 2J can be understood as a 2-D rendering of the 3-D features of the structure of the pillar constrictions shown in FIG. 2I, thus illustrating constrictions that would be seen in a plan view rather than in a cross-sectional view.)

Three-dimensional structures may need longer and/or more concentrated exposure to precursors to allow the innermost and bottommost areas to be filled. Three-dimensional structures can be particularly challenging when employing molybdenum halide and/or molybdenum oxyhalide precursors because of their proclivity to etch, with longer and more concentrated exposure allowing for more etch as parts of the structure.

FIGS. 2K and 2L show examples of an asymmetric trench structure DRAM bWL. Some fill processes for DRAM bWL trenches can distort the trenches such that the final trench width and resistance Rs are significantly non-uniform. FIG. 2K shows an unfilled feature 261 and filled feature 265 that exhibits line bending after fill. In this example, the features are a narrow asymmetric trench structure DRAM bWL. As shown, multiple features 283 are depicted on a substrate These features 283 are spaced apart, and in some embodiments, adjacent features have a pitch between about 20 nm and about 60 nm or between about 20 nm and 40 nm. The pitch is defined as the distance between the middle axis of one feature to the middle axis of an adjacent feature. The unfilled features 261 may be generally V-shaped, as shown in feature 283, having sloped sidewalls where the width of the feature narrows from the top of the feature to the bottom of the feature. The features widen from the feature bottom 273b to the feature top 273a. After some fill operations, line bending may be observed within the filled feature 265. Without being bound by a particular theory, it is believed that a cohesive force between opposing surfaces of a trench pulls the trench sides together, as depicted by arrows 267. This phenomenon is illustrated in FIG. 2L and may be characterized as “zipping up” the feature. As the feature 283 is filled, more force is exerted from a center axis 299 of the feature 283, causing line bending. For example, molybdenum may be deposited on the sidewalls of the feature 283. Deposited molybdenum 284a and 284b on sidewalls of feature 283 thereby interact in close proximity, where molybdenum-molybdenum bond radius r is small, thereby causing cohesive interatomic forces between the smooth growing surfaces of molybdenum and pulling the sidewalls together, thereby causing line bending. Described below are methods of filling features to reduce line bending.

Provided below are methods of filling features with molybdenum. The methods described herein include deposition, etch, and clean operations, which may be used to fill substrate features such as those described above. As described above, molybdenum offers several benefits over other metals such as cobalt (Co), ruthenium (Ru), and tungsten (W): (i) barrier-less and liner-less molybdenum film deposition is more feasible on oxide and nitride as compared to Co, Ru, and W, (ii) molybdenum resistivity scaling is better than W, (iii) molybdenum intermixing with underlying Co is not expected compared to Ru intermixing with Co at less than 450° C., and (iv) there is relatively easy molybdenum integration into current W schemes compared to Co and Ru.

Examples of feature fill for horizontally-oriented and vertically-oriented features are described below. It should be noted that in at least most cases, the examples are applicable to both horizontally-oriented and vertically-oriented features. Horizontally-oriented features generally refer to features oriented such that the feature axis is parallel to the plane of the substrate surface. Vertically-oriented features generally refer to features oriented such that the feature axis is orthogonal to the plane of the substrate surface.

Deposition of molybdenum as described herein involves reacting a Mo-containing precursor, also referred to as a molybdenum precursor. In some embodiments, a molybdenum precursor is a molybdenum chloride (MoClₓ) compound, also referred to as a molybdenum chloride precursor or MoClₓ precursor. Molybdenum chloride precursors are given by the formula MoClₓ, where x is 2, 3, 4, 5, or 6, and include molybdenum dichloride (MoCl₂), molybdenum trichloride (MoCl₃), molybdenum tetrachloride (MoCl₄), molybdenum pentachloride (MoCl₅), and molybdenum hexachloride (MoCl₆). In some embodiments, MoCl₅ or MoCl₆ are used. While the description chiefly refers to MoClₓ precursors, in other embodiments, other molybdenum halide precursors may be used. Molybdenum halide precursors are given by the formula MoX_{z}, where X is a halogen (fluorine (F), chlorine (Cl), bromine (Br), or iodine (I)) and z is 2, 3, 4, 5, or 6. Examples of MoX_{z} precursors include molybdenum fluoride (MoF₆). In some embodiments, a non-fluorine-containing MoX_{z} precursor is used to prevent fluorine etch or incorporation. In some embodiments, a non-bromine-containing and/or a non-iodine-containing MoX_{z} precursor is used to prevent etch or bromine or iodine incorporation.

In some embodiments, the feature may be filled using a molybdenum oxyhalide precursor. Molybdenum oxyhalide precursors are given by the formula MoO_{y}X_{z}, where X is a halogen (fluorine (F), chlorine (Cl), bromine (Br), or iodine (I)), and y and z are numbers greater than 0 such that MoO_{y}X_{z} forms a stable compound Examples of molybdenum oxyhalides include molybdenum dichloride dioxide (MoO₂Cl₂), molybdenum tetrachloride oxide (MoOCl₄), molybdenum tetrafluoride oxide (MoOF₄), molybdenum dibromide dioxide (MoO₂Br₂), and the molybdenum iodides MoO₂I, and Mo₄O₁₁I. It should be understood that as used herein the term molybdenum oxyhalide precursor may refer to a molybdenum oxyhalide precursor as described above or a molybdenum-containing oxyhalide precursor that includes molybdenum, oxygen, a halide and one or more other elements. In some embodiments, molybdenum oxyhalide or molybdenum-containing oxyhalides may include multiple different balogens (e.g., F and Cl and/or I and/or Br, etc.). A feature may be filled with molybdenum using a MoClₓ precursor, MoO_{y}X_{z} precursor, or a combination thereof.

For deposition of molybdenum into the feature, the molybdenum precursor may be reacted with a co-reactant. Examples of co-reactants include hydrogen (H₂), silane (SiH₄), diborane (B₂H₆), germane (GeH₄), ammonia (NH₃), and hydrazine (N₂H₄).

In some embodiments, deposition of molybdenum may use a plasma-based process. Gas may be fed into a remote or in-situ plasma generator to generate plasma species. Examples of gas that may be used to generate plasma may be a hydrogen-containing gas, such as H₂, nitrogen-containing gas, such as N₂, and other gasses, such as Ar and NH₃. The plasma species may be inert or react with the molybdenum precursor to form a film.

A feature may be filled with molybdenum by atomic layer deposition (ALD) or chemical vapor deposition (CVD). Thermal ALD or plasma enhanced ALD (PEALD) may be used. Similarly, thermal CVD or plasma enhanced CVD (PECVD) may be used.

ALD is a surface-mediated deposition technique in which doses of a precursor and a reactant are sequentially introduced into a deposition chamber. One or more cycles of sequential doses of a molybdenum precursor and reactant may be used to deposit Mo. For example, in the deposition of an initial molybdenum layer, MoCl₅ may be used as a precursor and H₂ as a reducing agent. Doses of MoCl₅ and H₂ are sequentially introduced into the deposition chamber with a purge gas, such as argon, flowed between. For ALD, the temperature of the substrate and the pressure of the chamber may be controlled. For example, the substrate may be heated between 300° C. and 800° C., e.g., between 650° C. and 750° C. In some embodiments, the chamber may be pressurized between 10 Torr and 90 Torr, e.g., between 30 Torr and 50 Torr. In some embodiments, the temperature and/or pressure may be used to control the rate of reactions. In some embodiments, the temperature and/or pressure may be used to control selectivity. This will be discussed further below.

In some embodiments, molybdenum fill may involve CVD. In a CVD process, the molybdenum precursor and reactant are in vapor phase together in the deposition chamber. Generally speaking, a CVD process fills a feature faster than an ALD process. In one example, the precursor may be a molybdenum chloride, such as MoCl₅, and is flowed into the chamber with a reactant, such as H₂. In this example, the wafer is simultaneously exposed to the precursor and reactant, which react and fill features with Mo.

In still some other embodiments, a feature may be filled using a pulsed CVD process. The pulsed CVD process continuously flows a reactant into a chamber while pulses of a precursor flow into the chamber. For example, H₂ gas may be flowed into the chamber and is continuously flowing into the chamber while MoCl₅ is intermittently flowing into the chamber. The temperature of the substrate and pressure in the chamber may be controlled during a CVD operation

Molybdenum may be selectively deposited into a feature using the methods described herein. In selective deposition, molybdenum fill may be deposited easier on a first material with respect to a second material, e.g., molybdenum deposition and growth may be easier on a metal material relative to molybdenum deposition and growth on a dielectric material. For example, a feature may have a sidewall surface of SiO₂ and a TiN plug in a bottom portion of the feature. In selective deposition, molybdenum is deposited into the feature and may grow on the TiN plug but not grow (or grow to a lesser extent) on the SiO₂ sidewall surfaces. In this example, by having molybdenum grow from the bottom of the feature on the TiN plug and not the sidewall surfaces, the feature avoids the line bending effect described above in FIG. 2L.

Process conditions such as the precursor gas, the reducing agent, process temperature, process pressure, and exposure time may affect the selectivity of the molybdenum film being deposited. Different precursor gases may have different process windows in which molybdenum film may be selectively deposited. For example, MoCl₅ has a higher selectivity than MoO₂Cl₂, i.e., under the same temperature and pressure conditions, the precursor gas of MoCl₅ may deposit molybdenum only on a conductive surface and not on a dielectric surface while a precursor gas of MoO₂Cl₂ may deposit molybdenum on both conductive and dielectric surfaces. Generally speaking, MoCl₅ gas has a large process window, i.e., large temperature and pressure range, where the precursor gas retains its selectivity. For example, MoCl₅ may be selectively deposited on a metal material with respect to a dielectric material where the process temperature is 250° C. to 800° C., e.g., 300° C. to 500° C. Generally speaking, higher process temperatures and higher process pressures reduce the selectivity of the deposited gas. For example, at higher temperatures, a precursor gas such as MoCl₅ may lose its selectivity and deposit molybdenum film on both a metal surface and a dielectric surface within a feature.

MoCl₅ may be reacted with different reactant to deposit a molybdenum film. Described below are examples of deposition of molybdenum film within a feature using a MoCl₅ precursor and different process controls. In a first example, the MoCl₅ precursor is reacted with a hydrogen (H₂) reactant using the deposition methods described above. In the description herein, the metal precursors are reacted with hydrogen (H₂) as a co-reactant (also referred to as a hydrogen reactant or H₂ reactant). However, other reactants may be used instead of hydrogen including other hydrogen-containing reactants such SiH₄, B₂H₆, NH₃, as appropriate. While reactants such as B₂H₆ and/or SiH₄ are stronger reducing agents, they can also result in higher resistivity. Thus, in some embodiments, using H₂ as described herein is advantageous. Process temperatures for selective deposition of the molybdenum film may be between 250° C. to 800° C., e.g., 300° C. to 500° C. At these temperatures, the molybdenum film is selectively deposited on conductive metal or metal compound surfaces, such as a TiN surface, in a feature relative to dielectric surfaces. The molybdenum film grows from the locations where the conductive surfaces are located in a feature. If the conductive surface is a TiN plug at the bottom of the feature, the molybdenum film may be deposited and grown from the bottom of the feature. In a second example, the molybdenum film may be deposited using the MoCl₅ precursor and the H₂ reactant, but at higher temperatures, i.e., above 800° C. This process window may have the molybdenum film deposited on both the dielectric and conductive surfaces within the feature. The deposition of the molybdenum film on the dielectric surface may be used to create a barrierless molybdenum layer in the feature, discussed in more detail below.

In yet another example, a MoCl₅ precursor is reacted with an ammonia (NH₃) reactant to deposit molybdenum film in a feature using the deposition processes described above In this embodiment, deposition of molybdenum film may have the process temperature between 200° C. to 700° C. Reacting MoCl₅ with NH₃ may have less selectivity than reacting with H₂ at similar temperatures. In this embodiment, molybdenum film may be deposited on both dielectric surfaces and conductive surfaces in the feature. The temperature process may be used to control the composition and crystallinity of the film deposited. At lower process temperatures, generally below 400° C., an amorphous molybdenum nitride film is deposited. At higher process temperatures, generally above 500° C., a crystalline molybdenum nitride film may be deposited. In between these ranges, a partially crystalline film having amorphous regions and crystalline regions may be deposited.

Etch operations may be used in the methods for filling features with molybdenum films. Etch operations remove materials such as metals and nitrides from the feature. For example, an etch process may partially or completely remove a liner layer from a feature. In another example, the etch process may be used to reduce the thickness of a liner layer. The etch operation, in some embodiments, may involve soaking the feature soaked in a molybdenum precursor gas. In some embodiments, an etch operation involves soaking the feature with a MoClₓ precursor such as MoCl₅. In some embodiments, the soak may be done continuously with the precursor gas. In some embodiments, the soak may be pulsed, cycling the MoClₓ precursor with a purge gas, such as argon (Ar). In still some other embodiments, the feature may be exposed to alternative doses of the MoClₓ precursor and a reactant, such as H₂.

The MoClₓ precursor may be used for both deposition and etch operations. For example, in certain process windows, a MoCl₅ precursor may concurrently grow a molybdenum film and etch away a metal or metal compound film in the feature. The process is considered a net etch operation if the rate of material removed is greater than the material deposited by the precursor. The speed at which the precursor deposits material and etches material may be controlled by a variety of process conditions, including the type of reactant used and the process temperature. Generally speaking, the lower the temperature, the higher the ratio of etching away material is relative to deposition of material. At higher temperatures, the same precursor and reactant may be used as a net deposition operation, i.e., the amount of material deposited is greater than the material removed. For example, MoCl₅ precursor and H₂ reactant may be used in an etch operation when the process temperature is below 400° C. The same precursor of MoCl₅ and H₂ reactant may be used in a deposition operation when the process temperature is above 550° C.

In some embodiments, the MoClₓ precursor at high temperatures, e.g., above 550° C., may continue to etch material at a faster rate than depositing material. For example, MoCl₅ may be used to etch a feature by a soak without a reactant. In this example, the temperature may be as high as 700° C. and will continue to etch away material from the feature. In operations where the feature is soaked in a MoCl₅ without a reactant, the increased temperature may increase the rate at which material is etched from the feature.

A feature may have surface oxide or contaminants on it. For example, the surface of an underlying TiN, WN, or W layer may be oxidized. If left, the oxidized surface can result in higher resistivity. Clean operations are used to remove such oxides and contaminants. In some embodiments, the clean operation may have the feature soaked in a molybdenum precursor gas, typically a molybdenum halide. Similar to the etch operations described above, the precursor gas may be a MoClₓ precursor. In some embodiments, the soak may be done continuously. In some embodiments, the soak may be pulsed, cycling MoClₓ and a purge gas, such as argon (Ar). The precursor may be a non-oxygen Cl-containing molybdenum compound able to remove oxidation from the feature's surfaces. Examples of MoClₓ compounds are given above. A Cl-containing precursor may be used where traditional cleaning with thermal or plasma H₂ does not work, such as where the oxidized surface is stable on the surface material. A Cl-containing precursor is less likely to over-etch a feature's liner layer or attack a feature's surfaces than an F-containing compound.

In some embodiments, filling a feature can involve depositing a nucleation layer. A nucleation layer is a thin layer that supports bulk deposition. It may be conformal to the feature. In many embodiments, a nucleation layer is deposited by an ALD process. In some embodiments, a molybdenum nucleation layer is deposited using one or more of a boron-containing reducing agent (e.g., B₂H₆) or a silicon-containing reducing agent (e.g., SiH₄) as a co-reactant. For example, one or more S/molybdenum cycles or Mo/S cycles may be used to deposit a molybdenum nucleation layer. In another example, one or more B/molybdenum cycles or Mo/B cycles may be used to deposit a molybdenum nucleation layer on which a bulk molybdenum layer is deposited. B refers to a pulse of diborane or other boron-containing reducing agent and S to a pulse of silane or other silicon-containing reducing agent, such that S/molybdenum refers to a pulse of silane followed by a pulse of a Mo-containing precursor. B/molybdenum and S/molybdenum cycles (or Mo/B and/or Mo/S) may both be used to deposit a molybdenum nucleation layer, e.g., x(B/Mo)+y(S/Mo), with x and y being integers. Examples of boron-containing reactants include diborane (B₂H₆), alkyl boranes, alkyl boron, aminoboranes (CH₃)₂NB(CH₂)₂, carboranes such as C₂BₙHₙ₊₂, and other boranes. Examples of boranes include BₙHₙ₊₄, BₙHₙ₊₆, BₙHₙ₊₈, BₙHₘ, where n is an integer from 1 to 10, and m is a different integer than m. Examples of silicon-containing reducing agents include silane (SiH₄) and other silanes such as disilane (Si₂H₆).

In some embodiments, deposition of a molybdenum nucleation layer may involve using a non-oxygen-containing precursor, e.g., molybdenum hexafluoride (MoF₆) or molybdenum pentachloride (MoCl₅). Oxygen in oxygen-containing precursors may react with a silicon- or boron-containing reducing agent to form MoSiₓO_{y} or MoBₓO_{y}, which are impure, high resistivity films. In some embodiments, oxygen-containing precursors may be used for nucleation layer deposition with oxygen incorporation minimized. Oxygen incorporation can be minimized by high reducing agent flows (e.g., greater than 100:1 volumetric flow rate of reducing agent to oxygen-containing molybdenum precursor).

In some embodiments, Hz may be used as a reducing gas for molybdenum nucleation layer deposition instead of a boron-containing or silicon-containing reducing gas. Example thicknesses for deposition of a molybdenum nucleation layer range from 5 Å to 30 Å. Films at the lower end of this range may not be continuous; however, as long as they can help initiate continuous bulk molybdenum growth, the thickness may be sufficient.

In some embodiments, the reducing agent pulses during deposition of a nucleation or bulk molybdenum layer may be done at lower substrate temperatures than the molybdenum precursor pulses. For example, or B₂H₆ or a SiH₄ (or other boron-or silicon-containing reducing agent) pulse may be performed at a temperature below 300° C., with the molybdenum pulse at temperatures greater than 300° C.

In some embodiments, the reducing agent is NH₃ or other nitrogen-containing reducing agents such as hydrazine (N₂H₄). NH₃ chemisorption on dielectrics is more favorable than that of H₂. In some embodiments, the reducing agent and precursor are selected such that they react without reducing agent dissociation. NH₃ reacts with metal oxychlorides and metal chlorides without dissociation. This is in contrast to, for example, ALD from metal oxychlorides that use H₂ as a reducing agent; H₂ dissociates on the surface to form adsorbed atomic hydrogen, which results in very low concentrations of reactive species and low surface coverage during initial nucleation of metal on the dielectric surface. By using NH₃ and metal oxychloride or metal chloride precursors, nucleation delay is reduced or eliminated at deposition temperatures up to hundreds of degrees lower than used by H₂ reduction of the same metal precursors.

In some embodiments, the reducing agent may be a boron-containing or silicon-containing reducing agent such as B₂H₆ or SiH₄. These reducing agents may be used with metal chloride precursors, with metal oxychlorides; however, the B₂H₆ and SiH₄ may react with water formed as a byproduct during the ALD process and form solid B₂O₃ and SiO₂. These are insulating and can remain in the film, increasing resistivity. The use of NH₃ also has improved adhesion over B₂H₆ and SiH₄ ALD processes on certain surfaces, including Al₂O₃. The resulting nucleation layer is generally not a pure elemental film but a metal nitride or metal oxynitride film. In some embodiments, there may be residual chlorine or fluorine from the deposition, particularly if the deposition is performed at low temperatures. In some embodiments, there may be no more than a trace amount of residual chlorine or fluorine. In some embodiments, the nucleation layer is an amorphous layer. Impurities in the film (e.g., oxygen, NH₃, chlorine, or other halogens) facilitate the growth of an amorphous microstructure. In some embodiments, the nucleation layer as deposited is an amorphous molybdenum oxynitride layer or an amorphous molybdenum nitride layer. The amorphous character templates large grain growth in the subsequently deposited conductor. The surface energy of nitride or oxynitride relative to an oxide surface is much more favorable than that of a metal on an oxide surface, facilitating formation of a continuous and smooth film on the dielectric. This allows formation of thin, continuous layers. Example thicknesses of the nucleation layer range from 5-30 Å as deposited. Depending on the temperature, this may be about 5-50 ALD cycles, for example.

As described below, during subsequent processing, the nucleation layer may be converted to a pure (or less impure) elemental metal film with the thickness decreasing. The surface on which the nucleation layer is deposited depends on the particular application. In some embodiments, the nucleation layer is deposited directly on a dielectric (e.g., silicon oxide, aluminum oxide, silicon nitride, etc.) surface. In some embodiments, the nucleation layer is deposited directly on a titanium nitride or other surface.

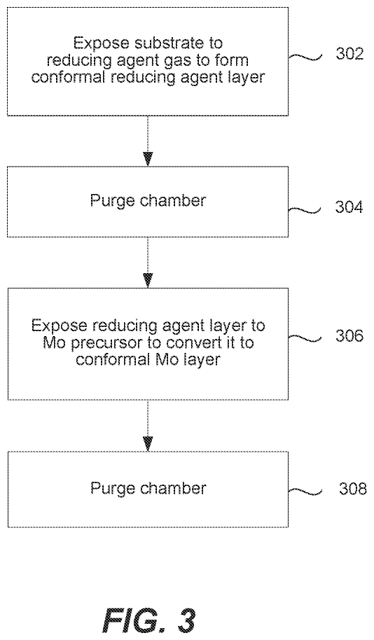

In some embodiments, ALD formation of a molybdenum layer can be initiated by a reducing agent layer. An example of such a process is shown in the flow diagram in FIG. 3. In operation 302, the substrate is exposed to a reducing agent gas to form a reducing agent layer. In some embodiments, the reducing agent gas may be a silane, a borane, or a mixture of a silane and diborane. Further examples of reducing agents are given below. In some implementations, the reducing agent layer may include silicon or silicon-containing material, phosphorous or a phosphorous-containing material, germanium or a germanium-containing material, boron or boron-containing material that is capable of reducing a molybdenum precursor and combinations thereof. According to various embodiments, hydrogen may or may not run in the background. (While hydrogen can reduce tungsten precursors, it does not function as a reducing agent in a gas mixture with a sufficient amount of stronger reducing agents such as silane and diborane.) In some embodiments, the reducing agent gas is a mixture including a small amount of a boron-containing gas, such as diborane, with another reducing agent. The addition of a small amount of a boron-containing gas can greatly affect the decomposition and sticking coefficient of the other reducing agent. It should be noted that exposing the substrate sequentially to two reducing agents, e.g., silane and diborane, may be performed. However, flowing a mixture of gases can facilitate the addition of very small amounts of a minority gas, e.g., at least a 100:1 ratio of silane to diborane. In some embodiments, a carrier gas may be flowed In some embodiments, a carrier gas, such as nitrogen (N₂), argon (Ar), helium (He), or other inert gases, may be flowed during operation 302.

In some embodiments, a reducing agent layer may include elemental silicon (Si), elemental boron (B), elemental germanium (Ge), or mixtures thereof. For example, a reducing agent layer may include elemental Si and B. This is distinct from adsorbed silane or diborane molecules and can involve decomposition of the compounds in the reducing agent gas. The amount of B may be tailored to achieve a high deposition rate of the reducing agent layer but with low resistivity. In some embodiments, a reducing agent layer may have between 5% and 80% B for example, or between 5% and 50% B, between 5% and 30%, or between 5% and 20% B, with the balance consisting essentially of Si and in some cases, H. Hydrogen atoms be present, e.g., SiHₓ, BH_{y}, GeH₂, or mixtures thereof where x, y, and z may independently be between 0 and a number that is less than the stoichiometric equivalent of the corresponding reducing agent compound. In some embodiments, the composition may be varied through the thickness of the reducing agent layer. For example, a reducing agent layer may be 20% B at the bottom of the reducing agent layer and 0% B the top of the layer. The total thickness of the reducing agent layer may be between 10 Å and 50 Å, and is some embodiments, between 15 Å and 40 Å, or 20 Å and 30 Å. The reducing agent layer conformally lines the feature.

The substrate temperature during operation 302 may be maintained at a temperature T1 for the film to be conformal. If the temperature is too high, the film may not conform to the topography of the underlying structure. In some embodiments, step coverage of greater than 90% or 95% is achieved. For silane, diborane, and silane/diborane mixtures, conformality is excellent at 300° C. and may be degraded at temperatures of 400° C. or higher. Thus, in some embodiments, the temperature during operation 302 is at most 350° C., or even at most 325° C., at most 315° C., or at most 300° C. In some embodiments, temperatures of less than 300° C. are used. For example, temperatures may be as low as 200° C.

Operation 302 may be performed for any suitable duration. In some examples, Example durations include between about 0.25 seconds and about 30 seconds, about 0.25 seconds and about 20 seconds, about 0.25 seconds and about 5 seconds, or about 0.5 seconds and about 3 seconds.

In operation 304, the chamber is optionally purged to remove excess reducing agents that did not adsorb to the surface of the substrate. A purge may be conducted by flowing an inert gas at a fixed pressure, thereby reducing the pressure of the chamber and re-pressurizing the chamber before initiating another gas exposure. Example inert gases include nitrogen (N₂), argon (Ar), helium (He), and mixtures thereof The purge may be performed for a duration between about 0.25 seconds and about 30 seconds, about 0.25 seconds and about 20 seconds, about 0.25 seconds and about 5 seconds, or about 0.5 seconds and about 3 seconds.

In operation 306, the substrate is exposed to a molybdenum precursor at a substrate temperature T2. The use of oxygen-containing precursors can lead to impurity incorporation and higher resistivity. However, if oxygen is incorporated, a very thin, possibly discontinuous reducing agent layer may be used for an acceptable resistivity. In some embodiments, a carrier gas, such as nitrogen (N₂), argon (Ar), helium (He), or other inert gases, may be flowed during operation 306. Examples of temperatures are 500° C. to 700° C.

Operation 306 may be performed for any suitable duration. In some embodiments, it may involve a soak of the molybdenum precursor, and in some embodiments, a sequence of molybdenum precursor pulses. According to various embodiments, operation 306 may or may not be performed in the presence of H₂. If H₂ is used, in some embodiments, it and the Mo-containing precursor may be applied in an ALD-type mode. For example:
Pulse of H₂
Argon purge
Pulse of Mo-containing precursor with or without H₂ in background
Argon purge
Repeat

The substrate temperature T2 is high enough that the Mo-containing precursor reacts with the reducing agent layer to form elemental Mo. The entire reducing agent layer is converted to Mo. In some embodiments, the temperature is at least 450° C., and may be at least 550° C. to obtain conversion of at or near 100%. The resulting feature is now lined with a conformal film of Mo. It may be between 10 Å and 50 Å, and in some embodiments, between 15 Å and 40 Å, or 20 Å and 30 Å. In general, it will be about the same thickness as the reducing agent layer. In some embodiments, it may be up to 5% thicker than the reducing agent layer due to volumetric expansion during the conversion. The chamber may be purged in an operation 308. The majority of a feature may be filled by deposition of a bulk molybdenum layer. A bulk molybdenum layer can be deposited on a nucleation layer, a reducing agent layer, or directly on an underlying surface as described above.

Bulk deposition can occur by an ALD or CVD process. In a CVD process, a reducing agent and a molybdenum precursor are co-flowed into a deposition chamber to deposit a bulk fill layer in the feature. An inert carrier gas may be used to deliver one or more of the reactant streams, which may or may not be pre-mixed. This operation generally involves flowing the reactants continuously until the desired amount is deposited. In certain implementations, the CVD operation may take place in multiple stages, with multiple periods of continuous and simultaneous flow of reactants separated by periods of one or more reactant flows diverted.

In some embodiments, a pulsed CVD process may be used in which H₂ or other co-reactant flows continuously while the molybdenum precursor is pulsed.

For conformal deposition and deposition into complex structures such as 3D NAND structures, ALD deposition of a bulk layer may be used. ALD deposition of a bulk layer involves exposure to alternating pulses of a molybdenum-containing precursor and a reducing agent, separated by an inert purge gas, using the molybdenum precursors described above. The same or different molybdenum precursor used in nucleation layer or reducing agent layer deposition may be used for bulk deposition. In contrast to nucleation layer deposition in which a strong reducing agent such as diborane or silane may be used, hydrogen is often the reducing agent for bulk deposition.

In some embodiments, a nucleation layer may be converted to an elemental molybdenum layer. This may also be characterized as removing impurities, i.e., any non-metal constituent. The nucleation layer may have greater impurities than the subsequently deposited elemental molybdenum layer, but they are sufficiently removed such that the stack resistivity is the same or similar to a stack that does not include a nucleation layer. As described above, in some embodiments, a molybdenum oxynitride or molybdenum nitride layer may be used as a nucleation layer. Also, in some embodiments, a molybdenum oxide layer may be used as a nucleation layer.

According to various embodiments, one or more of the following may be employed to facilitate the conversion of the nucleation layer to an elemental molybdenum film: 1) depositing the bulk molybdenum layer at a higher temperature (e.g., 550° C.) than the nucleation layer is deposited, 2) performing lower temperature ALD H₂/molybdenum precursor cycles, and 3) in-situ deposition of the bulk molybdenum layer, such that the nucleation layer is not exposed to air or otherwise oxidized before bulk deposition of molybdenum. Molybdenum oxynitrides, in particular, are relatively easy to convert to elemental metal. The resulting converted nucleation layer and pure metal layer may each be characterized as having fewer than 1% atomic impurities.

As described above in FIG. 1B, molybdenum may be deposited in a feature without a barrier layer, i.e., the molybdenum is deposited on a dielectric surface in the feature. In some embodiments, a reducing agent layer, as described above with reference to FIG. 3, may be used. In these embodiments, the reducing agent may be deposited into the feature. As described in operation 308, a subsequent deposition using a molybdenum precursor may convert the reducing agent layer into Mo. In some embodiments, molybdenum may be deposited directly onto the dielectric layer by either a CVD or ALD process using a molybdenum chloride or molybdenum oxyhalide precursor with a reactant as described above.

In a first example, molybdenum may be deposited into a feature with dielectric surfaces, such as SiO₂, using seed crystals. The process uses a molybdenum chloride precursor such as MoCl₅ and a reactant such as H₂. In some embodiments, NH₃ may be used as a reactant. As described above, MoCl₅ is highly selective and may resist growing directly on the dielectric surface compared to conductive surfaces. However, given a long enough exposure time of the precursor and reactant to the SiO₂ surfaces, molybdenum seed crystals will form on the SiO₂. The exposure time of the molybdenum precursor and reactant to form seed crystals on the dielectric material, due to the precursor selectivity, is longer than typical exposure time when depositing molybdenum on a nucleation layer or plug. Once a seed crystal forms on the dielectric layer, molybdenum may be selectively deposited on the seed crystals formed using the same precursor and reactants.

Forming a seed crystal can involve one or more of the following. In some embodiments, a long exposure of the molybdenum chloride precursor and reactant, such as H₂, to SiO₂ surfaces allows molybdenum seed crystals to form on the SiO₂. For example, molybdenum seed crystals may form on the dielectric material after 200 to 600 ALD cycles using MoCl₅ as a precursor and H₂ as a reactant. In another embodiment, depositing a relatively high amount of reactant compared to the precursor may be used to generate molybdenum seed crystals on dielectric surfaces. During molybdenum seed crystal formation, the concentration of precursor may be reduced, thus increasing the ratio of reactant relative to precursor deposited. In the example of using a MoCl₅ precursor and H₂ reactant, having a relatively high ratio of H₂ to MoCl₅ shortens the deposition delay on the dielectric material and allows seed crystals to generate faster. For seed crystal formation, the concentration of precursor gas may be reduced by up to 10×, e.g., 5×, the normal precursor concentration during normal deposition operations. For example, in a typical ALD processing, the precursor concentration may be 1-2% of the gas, i.e., the gas is 98% carrier gas and 2% precursor. In seed crystal formation, the precursor concentration may be reduced up to 10×, such that the precursor concentration is as low as 0.1% of the gas. In some embodiments, process temperature may be increased to improve seed crystal formation. For example, process temperature may be above 500° C. during seed crystal formation. In some embodiments, the temperature may be above 500° C. during seed crystal formation and may be reduced to below 500° C. for selective growth of molybdenum on the seed crystals formed on the dielectric material.

In some embodiments, a molybdenum oxyhalide such as MoO₂Cl₂ may be used as the precursor to form molybdenum seed crystals on dielectric surfaces. In these embodiments, the seed crystal may form faster on the dielectric material than seed crystals formed using the molybdenum chloride precursor. However, the molybdenum film deposited may be oxidized.

In some embodiments, molybdenum may be selectively deposited on a conductive metal plug formed in a feature. In these embodiments, a feature may have a plug made of a conductive metal, such as TiN, in the feature's bottom on which molybdenum is selectively deposited. The feature may also have a sidewall surface made of a dielectric material. Using selective deposition techniques (i.e., controlling process parameters such as temperature, pressure, and reactants) described above, molybdenum may be deposited using a molybdenum halide or molybdenum oxyhalide precursor such that the molybdenum is selective to the conductive metal plug. The molybdenum grows on the conductive metal plug and not on the dielectric sidewalls.

In embodiments where the feature does not have a conductive metal plug, a molybdenum plug can be formed at the bottom of the feature by depositing a molybdenum chloride precursor and a hydrogen reactant using the methods described above. The molybdenum plug may form when deposition occurs using (i) a relatively high ratio of a molybdenum chloride precursor relative to a H₂ reactant, (ii) a relatively high process pressure compared to selective deposition, or (iii) a combination thereof. In some embodiments, deposition into a feature using a high ratio of the molybdenum chloride precursor creates a net etch effect on the top of the feature and a net deposition effect at a feature bottom, allowing a molybdenum plug to form on the bottom of the feature. A feature bottom is the innermost surface of a feature connected by sidewalls. In some embodiments, the molybdenum plug may be formed at lower temperatures, e.g., below 450° C. The molybdenum plug may be formed using a CVD or pulsed CVD process. In the example of a pulsed CVD process, a H₂ reactant may continuously flow into the feature, and the MoCl₅ precursor may be pulsed at durations from 0.5 to 2.5 seconds with a concentration between 0.1% to 2%. Once the molybdenum plug is formed in a feature bottom, the process parameters may be changed to selectively deposit molybdenum on the molybdenum plug within the feature.

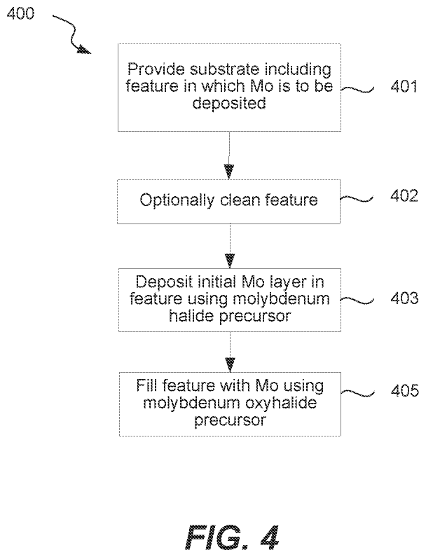

FIG. 4 is a process flow diagram illustrating a method to fill a feature with a molybdenum (Mo) film. Method 400 begins with providing a substrate including a feature in which molybdenum is to be deposited in an operation 401. The substrate may be provided to a semiconductor processing tool. The feature may be a trench, via, or any of the features described above in FIGS. 2A-2L. In some embodiments, the feature is formed in a dielectric material. Molybdenum may be deposited in the feature to make electrical contact with an underlying layer. Examples of underlying layers include metals, metal silicides, and semiconductors. Examples of metals include Co, Ru, copper (Cu), W, Mo, nickel (Ni), iridium (Ir), rhodium (Rh), tantalum (Ta), and Ti. Examples of metal silicides include TiSiₓ, nickel silicide (NiSiₓ), molybdenum silicide (MoSiₓ), cobalt silicide (CoSiₓ), platinum silicide (PtSiₓ), ruthenium silicide (RuSiₓ), and nickel platinum silicide (NiPt_{y}Siₓ). Examples of semiconductors include silicon (Si), silicon germanium (SiGe), and gallium arsenide (GaAs) with or without semiconductor dopants such as carbon (C), arsenic (As), boron (B), phosphorus (P), tin (Sn), and antimony (Sb).

The feature generally has sidewall surfaces and may have a bottom surface. In some embodiments, the sidewall surfaces may be the same material as the bottom surface. For example, in some embodiments, the sidewall surfaces and the bottom surface are TiN. In some embodiments, the sidewall surfaces may be a different material than the material of the bottom surface. For example, the bottom surface may be a metal silicide, and the sidewall surface may be a silicon oxide, such as SiO₂. In some embodiments, the feature may have sidewall surfaces sloped. In some such embodiments, the sidewall surfaces intersect at a bottom of the feature.

Prior to any molybdenum deposition, a liner layer may line the unfilled feature and form the sidewall surfaces and/or bottom surface. In some embodiments, a liner layer lines the whole feature and forms the sidewall surfaces and bottom surface. In some other embodiments, the liner layer lines only a portion of the feature. For example, a TiN layer may line the sidewalls with the bottom surface unlined. Examples of materials for liner layers include metal nitrides (e.g., a TiN or tantalum nitride (TaN) barrier layer) and metals (e.g., a Ti adhesion layer).

In some embodiments, the feature surfaces are oxidized. Oxidation may be caused by exposing a feature's surfaces to air or other oxidizing conditions. For example, a metal silicide (MSiₓ where M is a metal) surface may be oxidized to oxidized metal silicide (MSiₓO_{y}) on exposure to air. Other examples of oxidized surfaces include oxidized metal nitrides (MNₓO_{y}), oxidized silicon (SiOₓ), and oxidized silicon-germanium (SiGeOₓ). (In the description herein, the subscripts x and y are used in formulas to denote non-zero numbers.)

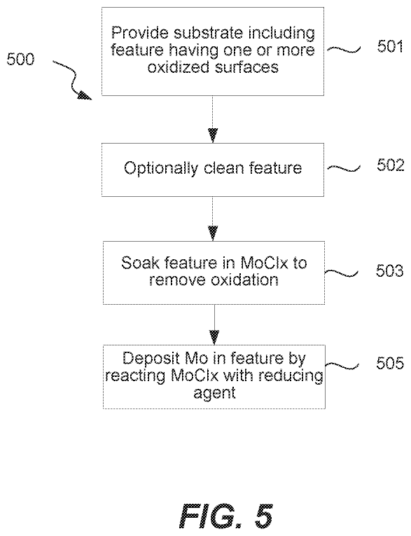

In some embodiments, oxidizing conditions occur in the course of substrate processing or transfer operations. In some embodiments, intentional oxidation is performed as described further below with reference to FIG. 5.

After providing a substrate including a feature in which molybdenum is to be deposited, an optional clean, operation 402, may be performed. The optional clean may be used to remove oxide on the feature's surfaces. In some embodiments, an in-situ clean process as described above may be used. The in-situ clean may use a molybdenum halide, such as MoCl₅. In some embodiments, a hydrogen plasma treatment, a thermal hydrogen treatment, or a reducing treatment may be used to reduce oxidized metal on a metal substrate at the feature bottom. In some embodiments, an atomic layer clean with a Cl-based plasma, a hydrogen fluoride (HF) vapor clean, an ammonium fluoride (NH₄F) clean, or a treatment using other reducing agents may be used to reduce oxide off a feature surface.

Once the substrate is provided, an initial molybdenum layer is deposited in the feature in operation 403. The initial molybdenum layer is deposited by an ALD method. The initial molybdenum layer is deposited by sequentially introducing a molybdenum precursor and a reducing agent into the deposition chamber. One or more cycles of sequential doses of the molybdenum precursor and reducing agent may be used to deposit the initial molybdenum layer. In some embodiments, the initial molybdenum layer may be deposited conformally to the feature. A conformal molybdenum layer may be between 1 and 5 nm in some embodiments. In some embodiments, it is no more than 2 nm thick. In some embodiments, molybdenum may be deposited non-conformally such that it is selectively deposited on the bottom of the feature relative to the sidewalls, e.g., depositing a molybdenum plug in the bottom of the feature.

For deposition of the initial molybdenum layer, the molybdenum precursor is a molybdenum halide precursor. A MoClₓ precursor is used in some embodiments. As discussed above, other MoX_{z} precursors may be used in other embodiments. Examples of reducing agents used are discussed above. A non-oxygen-containing molybdenum precursor prevents oxidation of the feature's surfaces. It also prevents oxygen from being incorporated into the initial molybdenum layer. Oxidation increases contact resistance. The lack of oxidation and oxygen incorporation ensures the contact resistance remains low.

During the ALD process, the temperature of the substrate and the pressure of a chamber may be controlled. In some embodiments, the substrate may be heated between 300° C. and 500° C., e.g., between 350° C. and 450° C. In some embodiments, the chamber may be pressurized to at least 10 Torr, e.g., to at least 30 Torr, or to at least 50 Torr.

In some embodiments, process parameters such as temperature may be used to control selectivity. For example, molybdenum may be deposited selectively on a metal silicide surface or metal nitride surface with respect to a dielectric material surface by using a lower temperature than for conformal deposition. For example, in some embodiments, a temperature below 400° C. is used.

After the initial molybdenum layer is deposited, the feature is filled with molybdenum using a molybdenum oxyhalide precursor in operation 405. As indicated above, examples of MoO_{y}X_{z} precursors include MoO₂Cl₂, MoOCl₄, MoOF₄, MoO₂Br₂, MoO₂I, and Mo₄O₁₁I. The feature may be filled using ALD, plasma enhanced ALD, chemical vapor deposition (CVD), or plasma enhanced CVD. For ALD or CVD, H₂ may be the reducing agent. Molybdenum deposits more quickly using a molybdenum oxyhalide precursor than the MoClₓ precursor used to form the initial molybdenum layer. For example, a MoO_{y}X_{z} precursor may deposit molybdenum at a deposition rate at least twice as fast as a MoClₓ precursor for a non-plasma process. Plasma enhanced processes may be used to fill features at lower temperatures and/or increase deposition rates.

FIG. 5 is a process flow diagram illustrating an in-situ clean method to clean an oxidized feature. Method 500 begins with providing a substrate including a feature having one or more oxidized surfaces in operation 501. The substrate may be provided to a semiconductor processing tool.

Like the features referenced in operation 401 of FIG. 4, the feature has sidewall surfaces and may have a bottom surface. In some embodiments, the feature may be formed in a dielectric layer as a trench or via to connect to an underlying layer. Other examples of features are described above in FIGS. 2A-2L. Examples of materials that form the bottom surface and sidewall surfaces, including liner layers, are given above with reference to operation 401 of FIG. 4. In the discussion herein for FIG. 5, the feature has a bottom surface and sidewall surfaces. It should be appreciated that the method may be used for any feature provided on a substrate with an oxidized surface.

The feature provided has at least one oxidized surface. In some embodiments, both the bottom surface and the sidewall surfaces are oxidized. In some other embodiments, only some surfaces (e.g., only the bottom surface) are oxidized. The oxidized surface may be caused by exposing the surface to oxidizing conditions. Examples of oxidizing conditions include exposing the surface to air and treating the surface with an oxygen-based thermal or plasma treatment. In some embodiments, oxidizing conditions occur in the course of substrate processing or transfer operations. In some embodiments, an intentional oxidation is performed. Examples of oxidized surfaces are given above with reference to FIG. 4.

After providing the substrate, an optional intentional oxidization of the surface may be performed. Intentional oxidation may occur through exposing the surface to air or treating the surface with an oxygen-based thermal treatment or an oxygen-plasma treatment. The intentional oxidation of the surface may be used to increase the oxidization of a liner layer, e.g., a TiN barrier layer. This increases the amount of liner layer that is removed during the in-situ clean. Thinning the liner layer in this manner lowers resistance in the feature.

After providing a substrate including a feature in which molybdenum is to be deposited, an optional clean, operation 502, may be performed. The optional clean may be used to remove oxide on the feature's surfaces. In some embodiments, a hydrogen plasma treatment, a thermal hydrogen treatment, or a reducing treatment is used to reduce oxidized metal on a metal substrate at the feature bottom. In some embodiments, an atomic layer clean with a Cl-based plasma, a hydrogen fluoride (HF) vapor clean, an ammonium fluoride (NH₄F) clean, or a treatment using other reducing agents may be used to reduce oxide on a feature surface.

Next, the feature undergoes a soak in operation 503. The feature is soaked in a molybdenum chloride (MoClₓ) precursor to remove oxidation from the feature's surfaces. In some embodiments, the soak may be done continuously. In some embodiments, the soak may be pulsed, cycling MoClₓ and a purge gas, such as argon (Ar). The precursor is a non-oxygen Cl-containing molybdenum compound able to remove oxidation from the feature's surfaces. Examples of MoClₓ compounds are given above. A Cl-containing precursor may be used where traditional cleaning with thermal or plasma H₂ does not work, such as where the oxidized surface is stable on the surface material.

In one example, a feature may have a TiN barrier layer as its liner layer. The liner layer may be oxidized to form a TiNₓO_{y} surface layer. Because TiNₓO_{y} is stable, H₂ processes may not efficiently remove TiNₓO_{y} from the TiN layer. Soaking the feature in a MoClₓ precursor, such as MoCl₅, effectively removes the oxide from the TiN liner layer. For relatively thin liners, a F-based precursor, such as tungsten fluoride (WF₆), may cause over-etching of the liner. The F-based precursor may attack the underlying surfaces, such as the feature's bottom surface. The in-situ clean process of FIG. 5 prevents over-etching of the TiN liner and attack on the underlying surfaces. In an example of a TiN barrier layer, the F-based precursor may attack it and/or any underlying metal silicide.

For the in-situ clean, the temperature of the substrate, the pressure of a chamber in the semiconductor processing tool, and the precursor exposure time to the feature may be controlled. In some embodiments, the substrate may be heated between 300° C. and 500° C., e.g., between 350° C. and 450° C. In some embodiments, the chamber may be pressurized to at least 10 Torr, e.g., at least 30 Torr, or at least 50 Torr. The total precursor exposure time to the feature may be at least 10 seconds, e.g., at least 60 seconds. As indicated above, the soak may be continuous or pulsed.

After the feature undergoes a soak and oxidation is removed from the feature's surfaces, molybdenum is deposited into the feature using MoClₓ in operation 505. The molybdenum deposition uses MoClₓ, the same precursor used to soak the feature in operation 503. The molybdenum deposited is an initial molybdenum layer. In some embodiments, Operation 505 may involve filling the feature using MoCl₅. In some other embodiments, the feature may be filled using a molybdenum oxyhalide precursor MoCl_{y}X_{z}. Examples of molybdenum oxyhalide precursors are given above. The feature may be filled using ALD or CVD, including thermal and plasma-enhanced ALD and CVD processes described above.

Feature fill may be non-selective or selective according to various embodiments. In some embodiments, feature fill may be selective to partially fill the feature, followed by a more conformal fill to complete feature fill. A non-selective deposition may be described herein as a conformal deposition in that the deposited layer conforms to the contour of the underlying feature. Such a deposited layer may have some thickness non-uniformity.

For the fill process in operation 505, the temperature of the substrate, the pressure of the chamber, and the reactant exposure time may be controlled. These process parameters may be used to control selectivity during bulk fill of the Mo. As in operation in 503, the substrate may be heated between 300° C. and 500° C., e.g., between 350° C. and 450° C. The chamber may be pressurized to at least 10 Torr, e.g., at least 30 Torr, or at least 50 Torr. The reactant exposure time may be at least 5 seconds, e.g., at least 15 seconds.

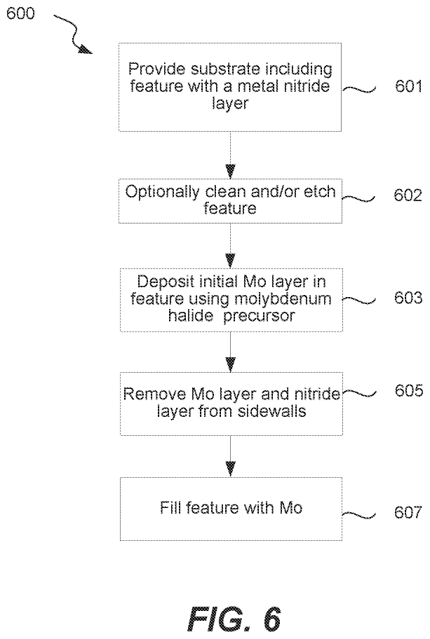

FIG. 6 is a process flow diagram illustrating a method to fill a feature having a protective nitride layer with a molybdenum film. The protective nitride layer may be used to protect a feature bottom and the underlying materials below a bottom surface of the feature. Method 600 begins with providing a substrate with a metal nitride layer in operation 601. The substrate may be provided to a semiconductor processing tool.

Similar to the feature referenced in operation 401 of FIG. 4, the feature generally has a bottom with a bottom surface and sides with sidewall surfaces. The feature may be formed in a dielectric layer and connects to an underlying layer. Examples of materials that form the bottom and sidewall are given above with reference to operation 401 in FIG. 4.

In the feature provided, the bottom surface is a metal nitride layer. Examples of a metal nitride are TiN and TiSiN. In some embodiments, the metal nitride layer may conformally line the feature, such that the sidewall surfaces and bottom surface is the metal nitride layer. In some embodiments, the sidewall surfaces may be a different material than the material of the bottom surface. For example, the bottom surface may be a metal nitride layer, and the sidewall surface may be a dielectric material.

In some embodiments, the bottom surface and sidewall surfaces are oxidized. Oxidation may be caused by exposing a feature's surfaces to air or other oxidizing conditions. In some embodiments, oxidizing conditions occur in the course of substrate processing or transfer operations. In some embodiments, an intentional oxidation is performed as described above in FIG. 5.

After providing a substrate with a metal nitride layer, an optional clean and/or optional etch may be performed in operation 602. The clean may be used to remove oxide from the field, sidewall surfaces, and bottom surfaces of the feature, while the optional etch may be used to remove part of the metal nitride layer on the sidewall or the field of the substrate. Examples of cleaning treatments are given above in operation 502 of FIG. 5.

If performed, operation 602 may involve soaking the feature in a molybdenum precursor to remove oxidation and/or remove or reduce the metal nitride layer from the feature. In some embodiments, the soak may be done continuously. In some embodiments, pulsed soak may be used, cycling the precursor gas while flowing a purge gas. In some embodiments, the precursor gas may be cycled alternatively with a purge gas. The precursor gas may be a molybdenum-containing halide compound. In some embodiments, the precursor gas is MoClₓ, e.g., MoCl₅. Examples of other MoClₓ precursors are given above.

For the clean/etch operation in 602, the temperature of the substrate, the pressure of a chamber in the semiconductor processing tool, and the precursor exposure time to the feature may be controlled. In some embodiments, the substrate may be heated between 300° C. and 500° C., e.g., between 350° C. and 450° C. In some embodiments, the chamber may be pressurized to at least 10 Torr, e.g., at least 30 Torr, or at least 50 Torr. The total precursor exposure time to the feature may be at least 10 seconds, e.g., at least 60 seconds. As indicated above, the soak may be continuous or pulsed.

In operation 603, an initial molybdenum layer is deposited into the feature. The initial molybdenum layer may be deposited by ALD. The initial molybdenum layer is formed by depositing one or more sequential doses of the molybdenum precursor and a reducing agent into the deposition chamber. The molybdenum precursor is a non-oxygen containing molybdenum precursor. The non-oxygen containing precursor prevents oxidation of the surfaces of the feature and helps ensure the contact resistance remains low. The non-oxygen containing molybdenum precursor may be a molybdenum-containing halide compound. An example of a non-oxygen containing precursor is a MoClₓ precursor, which is described above. In some embodiments, the precursor may be the same in operations 602 and 603. Examples of reducing agents are given above in operation 403 of FIG. 4. The initial molybdenum layer may be deposited selectively into the feature on the metal nitride layer. The molybdenum is deposited so that the molybdenum layer becomes the bottom surface of the feature. The conformal molybdenum layer may be between 1 and 5 nm in some embodiments. In some embodiments, it is no more than 2 nm thick.

For the deposition operation in 603, the temperature of the substrate, the pressure of a chamber in the semiconductor processing tool, and the precursor exposure time to the feature may be controlled. In some embodiments, the substrate may be heated between 350° C. and 700° C., e.g., between 375° C. and 475° C. In some embodiments, the chamber may be pressurized to at least 10 Torr, e.g., at least 30 Torr, or at least 50 Torr. The total precursor exposure time to the feature may be at least 10 seconds, e.g., at least 60 seconds. As indicated above, the soak may be continuous or pulsed. In some embodiments, the temperature of the substrate during operation 603 is greater than the temperature of the substrate in operation 602, e.g., at least 50° C., at least 100° C., at least 200° C. In some embodiments, the temperature of the substrate remains the same between operation 602 and operation 603. After the molybdenum layer is deposited, the molybdenum layer and the underlying metal nitride layer are removed from at least a portion of the sidewalls of the feature. Operation 605 may involve performing an etch operation similar to that described above with respect to operation 602. The etch is performed such that the metal nitride layer and the molybdenum layer on the bottom surface remain in the feature. The metal nitride layer and the molybdenum layer on the feature bottom surface may be used to protect an active junction on the feature bottom. The etch may use the same or different precursors described in the etch operation above described in operation 602. The etch in operation 605 may be “more aggressive” than the clean and/or etch performed in operation 602. A more aggressive etch in operation 605 may be performed at a higher temperature, higher pressure, longer exposure time of the precursor, or a combination thereof than that in operation 602.

The feature is filled with molybdenum in operation 607 after the metal nitride layer and molybdenum layer are removed from the sidewalls of the feature in operation 605. The feature may be filled by using ALD or CVD, including thermal and plasma-enhanced ALD and CVD processes. A molybdenum halide or molybdenum oxyhalide may be used as a precursor for the fill operation. In some embodiments, multiple precursors may be used to fill the feature. In one such embodiment, a molybdenum halide precursor may be used to deposit molybdenum into the feature, followed by a molybdenum oxyhalide precursor for a bulk molybdenum fill. For example, the feature may be initially filled using MoCl₅ as a precursor followed by a fill using MoO₂Cl₂. Examples of molybdenum halide precursors and molybdenum oxyhalide precursors are described above. The feature fill may be non-selective or selective according to various embodiments. In some embodiments, feature fill may be selective to partially fill the feature, followed by a more conformal fill to complete feature fill.

The fill process may use the same parameters discussed above in FIG. 5. Similar to the operation in 503, the substrate may be heated between 300° C. and 500° C., e.g., between 350° C. and 450° C. The chamber may be pressurized to at least 10 Torr, e.g., at least 30 Torr, or at least 50 Torr. The reactant exposure time may be at least 5 seconds, e.g., at least 15 seconds. In some embodiments, process parameters, such as temperature, may be used to control selectivity.

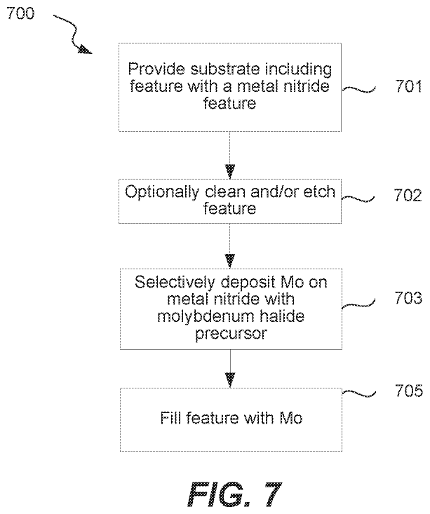

FIG. 7 is a process flow diagram illustrating a method to fill a feature having a nitride feature with a molybdenum (Mo) film. The nitride feature may be a nitride plug in the bottom of the feature or a nitride layer. Method 700 begins with providing a substrate with a metal nitride feature in operation 701. The substrate may be provided to a semiconductor processing tool.

The feature generally has two sidewall surfaces that meet at a bottom of the feature. The two sidewall surfaces generally are sloped such that the feature is “V-shaped.” It may be formed in a dielectric layer as a trench or via and connects to an underlying layer. Examples of materials that form the bottom and sidewall are given above with reference to operation 401 in FIG. 4.

In some embodiments, the nitride feature may be a nitride plug. In some embodiments, the nitride plug is a metal nitride plug. The nitride plug is at the bottom of the feature. In some embodiments, the metal nitride feature may be a metal nitride layer. In some embodiments, the metal nitride layer may conformally line the feature, such that the sidewall surfaces are the metal nitride layer. In some embodiments, the metal nitride layer may line a portion of the sidewall such that a bottom portion of the sidewall surface is the metal nitride layer and a top portion of the sidewall surface is a dielectric material. Examples of a metal nitride are TiN and TiSiN.

In some embodiments, the sidewall surfaces are oxidized. Oxidation may be caused by exposing a feature's surfaces to air or other oxidizing conditions. In some embodiments, oxidizing conditions occur in the course of substrate processing or transfer operations. In some embodiments, an intentional oxidation is performed as described above with reference to FIG. 5.

After providing a substrate with a metal nitride feature, an optional clean and/or optional etch may be performed in operation 702. The clean may be used to remove oxide from the field and feature surfaces, while the optional etch may be used to remove part of the metal nitride layer on the sidewall or the field of the substrate. Examples of cleaning treatments are given above in operation 502 of FIG. 5. After the optional etch, a metal nitride surface is at a bottom portion of the feature.

If performed, operation 702 may involve soaking the feature in a molybdenum precursor to remove oxidation and/or remove or reduce the metal nitride layer from the feature. In some embodiments, the etch may etch more material at the top of the feature relative to the bottom. In a first example, a metal nitride layer may conformally line the feature. The etch may remove the metal nitride layer at a top portion of the feature and leave the metal nitride layer at a bottom portion of the feature. In this example, the top portion of the sidewall surface may be a dielectric material, while the top portion of the sidewall surface may be a metal nitride layer. As discussed above in operation 602, the precursor gas may soak continuously, may be pulsed, or cycled with another gas such as a purge gas In some embodiments, the precursor gas may be a molybdenum-containing halide precursor. For example, the precursor gas may be MoClₓ. Examples of MoClₓ precursors are given above. In some embodiments, the etch may be a net etch as described above. In this example, the net etch may react molybdenum chloride with a reactant such as H₂. Molybdenum may be deposited in the bottom of the feature while the molybdenum chloride etches away part of the metal nitride liner at the top of the feature. For the clean/etch operation in 602, the temperature of the substrate, the pressure of a chamber in the semiconductor processing tool, and the precursor exposure time to the feature may be controlled. These process controls are similar to the process controls discussed in operation 602

As discussed above in operation 602, for ALD, the temperature of the substrate and the pressure of a chamber may be controlled. These process parameters may be used to control selectivity such that the molybdenum initial layer is initially deposited on the metal nitride surfaces on the bottom portion of the feature. In some embodiments, the substrate may be heated between 300° C. and 500° C., e g., between 350° C. and 450° C. In some embodiments, the chamber may be pressurized to at least 10 Torr, e.g., to at least 30 Torr, or to at least 50 Torr.

In operation 703, an initial molybdenum layer is selectively deposited onto the metal nitride feature at the bottom portion of the feature. In embodiments where the feature has a metal nitride layer, molybdenum is deposited on the metal nitride layer at the bottom portion of the sidewall surfaces in the bottom portion of the feature. In embodiments where the feature has a metal nitride plug, molybdenum is deposited on the metal nitride plug in the bottom of the feature. The initially molybdenum layer may grow upward from the metal nitride surfaces at the bottom of the feature. Molybdenum may be deposited by ALD, plasma enhanced ALD, CVD, or plasma enhanced CVD using a molybdenum halide precursor with a reactant. The molybdenum halide precursor may be a molybdenum chloride compound, such as MoCl₅, and the reactant may be H₂. Examples of additional precursors and reactants are listed above.

As discussed above in operation 603, for ALD, the temperature of the substrate and the pressure of a chamber may be controlled. These process parameters may be used to control selectivity such that the molybdenum initial layer is initially deposited on the metal nitride surfaces on the bottom portion of the feature. In some embodiments, the substrate may be heated between 350° C. and 700° C., e.g., between 375° C. and 475° C. In some embodiments, the chamber may be pressurized to at least 10 Torr, e.g., to at least 30 Torr, or to at least 50 Torr. In some embodiments, the temperature of the substrate during operation 703 is greater than the temperature of the substrate in operation 702, e.g., at least 50° C., at least 100° C. In some embodiments, the temperature of the substrate remains the same between operation 602 and operation 603.

After the initial molybdenum layer is deposited, the feature is filled with molybdenum in operation 705. The molybdenum fill is deposited on the initial molybdenum layer deposited in operation 703. The fill may be done using the same molybdenum halide precursor used in the previous operation or may be filled using a molybdenum oxyhalide precursor. The precursor may be deposited with a reactant such as H₂. The feature may be filled using ALD, plasma enhanced ALD, CVD, or plasma enhanced CVD.

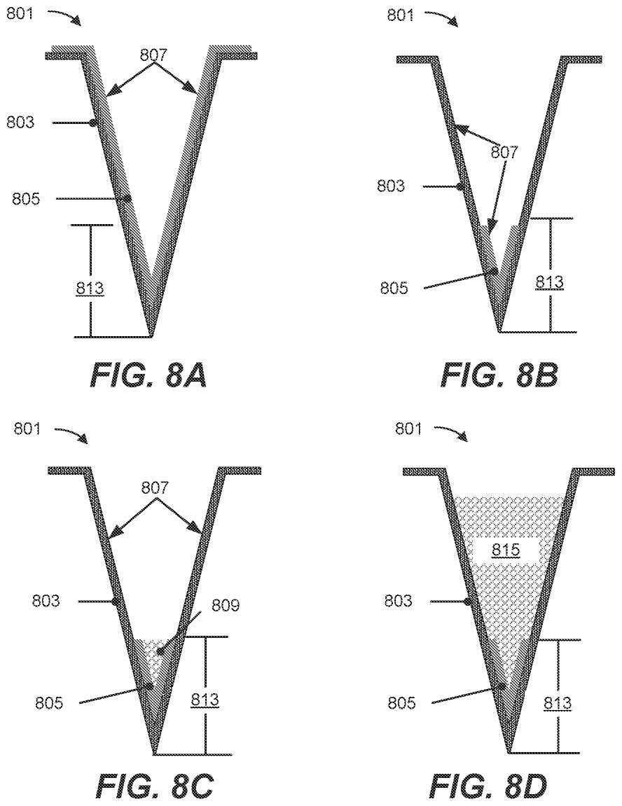

FIGS. 8A-8D show schematic examples of the process of FIG. 7. FIG. 8A shows a feature 801 formed in a dielectric material 803. The feature 801 has a metal nitride layer 805 conformally deposited into the feature 801. In some embodiments, the metal nitride layer 805 is a TiN layer. The metal nitride layer forms the two sidewall surfaces 807. The feature 801 is a V-shaped trench and has the sidewall surfaces 807 converge at a bottom portion 813 of the feature.

FIG. 8B shows the feature 801 after undergoing a clean and etch operation as described above in operation 702 of FIG. 7. The feature undergoes a soak using a MoClₓ precursor, which effectively removes the oxide. The soak also removes a top portion of the metal nitride layer 805 so that the metal nitride layer 805 remains in the bottom portion 813 of the feature 801. After the clean operation, each of the sidewall surfaces 807 has the metal nitride layer 805 on the bottom portion sidewall surfaces and the dielectric material 803 on the top portion of each of the sidewall surfaces.

FIG. 8C depicts the feature 801 after an initial molybdenum film 809 is deposited into the feature 801 as described above in operation 703 of FIG. 7. The initial molybdenum film 809 is selectively deposited such that the initial molybdenum layer is deposited on the metal nitride layer 805 surfaces in the bottom portion 813 of the feature 801. Minimal to none of the initial molybdenum film 809 is deposited on the dielectric material 803, which form the sidewall surfaces 807 in the upper portion of the feature 801. Thus, the molybdenum film 809 is deposited and filled up from the bottom portion 813 of the feature 801.

FIG. 8D shows the feature 801 after the feature is filled with molybdenum 815 as described in operation 705 of FIG. 7. The molybdenum fill is deposited on the initial molybdenum layer shown in FIG. 8C and grows up from the bottom portion 813 of the feature until the feature is filled with Mo. The feature may be filled using ALD, plasma enhanced ALD, CVD, or plasma enhanced CVD. In some embodiments, the fill uses a molybdenum oxyhalide precursor, such as MoO₂Cl₂. In some embodiments, the fill uses a molybdenum halide precursor, such as MoCl₅.

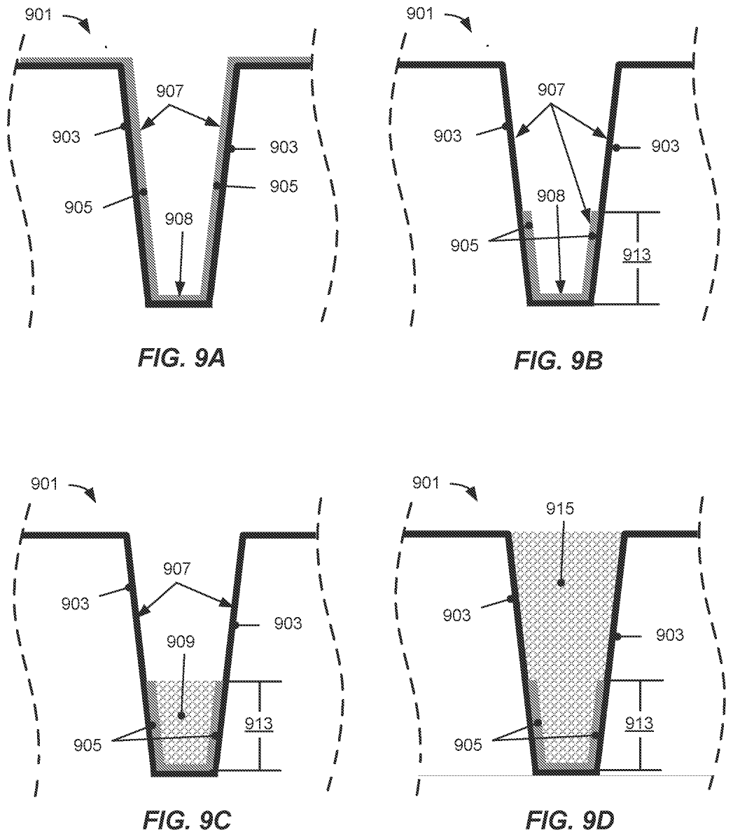

FIGS. 9A-9D show schematic examples of the process of FIG. 7. FIG. 9A shows a feature 901 formed in a dielectric material 903. The feature 901 has sidewall surfaces 907 and a bottom surface 908. The feature 901 has a metal nitride layer 905 conformally deposited into the feature 901. In some embodiments, the metal nitride layer 905 is a TiN layer. The metal nitride layer forms the two sidewall surfaces 907 and the bottom surface 908.

FIG. 9B shows the feature 901 after undergoing a clean and etch operation as described above in operation 702 of FIG. 7. The feature undergoes a soak using a MoClₓ precursor which, effectively removes the oxide. The soak also removes a top portion of the metal nitride layer 905 so that the metal nitride layer 905 remains in the bottom portion 913 of the feature 901. After the clean operation, each of the sidewall surfaces 907 has the metal nitride layer 905 on the bottom portion sidewall surfaces and the dielectric material 903 on the top portion of each of the sidewall surfaces. The metal nitride layer 905 is still the bottom surface 908 of the feature 901.

FIG. 9C depicts the feature 901 after an initial molybdenum film 909 is deposited into the feature 901 as described above in operation 703 of FIG. 7. The initial molybdenum film 909 is selectively deposited such that the initial molybdenum layer is deposited on the metal nitride layer 905 surfaces, i.e., the sidewall surfaces 907 in the bottom portion 913 of the feature 901 and the bottom surface 908. Minimal to none of the initial molybdenum film 909 is deposited on the dielectric material 903, which form the sidewall surfaces 907 in the upper portion of the feature 901. Thus, the molybdenum film 909 is deposited and filled up from the bottom portion 913 of the feature 901.

FIG. 9D shows the feature 901 after the feature is filled with molybdenum 915 as described in operation 705 of FIG. 7. The molybdenum fill is deposited on the initial molybdenum layer shown in FIG. 9C and grows up from the bottom portion 913 of the feature until the feature is filled with Mo. The feature may be filled using ALD, plasma enhanced ALD, CVD, or plasma enhanced CVD. In some embodiments, the fill uses a molybdenum oxyhalide precursor, such as MoO₂Cl₂. In some embodiments, the fill uses a molybdenum halide precursor, such as MoCl₅.

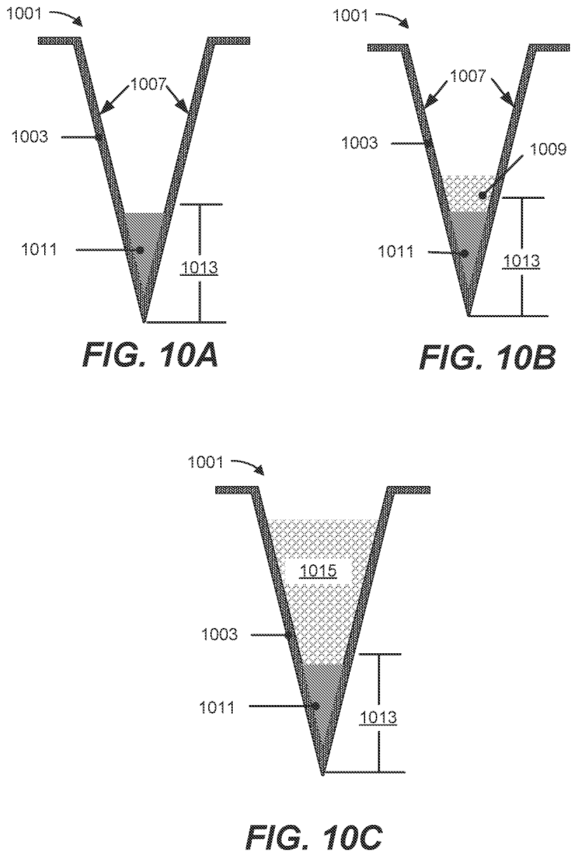

FIGS. 10A-10C show a second schematic example of the process of FIG. 7. FIG. 10A shows a feature 1001 formed in a dielectric material 1003. The feature 1001 is a V-shaped trench and has sidewall surfaces 1007 converge at a bottom portion 1013 of the feature. The sidewall surfaces 1007 are the dielectric material 1003. The feature 1001 has a metal nitride plug 1011 in the bottom portion 1013 of the feature 1001. In some embodiments, the metal nitride plug 1011 is a TiN plug.

FIG. 10B depicts the feature 1001 after an initial molybdenum layer 1009 is deposited into the feature 1001 as described above in operation 703 of FIG. 7. The initial molybdenum layer 1009 is selectively deposited onto the metal nitride plug 1011 in the bottom portion 1013 of the feature 1001. Similar to the schematic in FIG. 8C, little to none of the initial molybdenum layer 1009 is deposited on the dielectric material 1003 sidewall surfaces 1007.

FIG. 10C shows the feature 1001 after the feature is filled with molybdenum 1015 as described in operation 705 of FIG. 7. The molybdenum fill is deposited onto the initial molybdenum layer. The feature 1001 fills from the bottom portion 1013 of the feature and grows upward. The feature may be filled using ALD, plasma enhanced ALD, CVD, or plasma enhanced CVD. In some embodiments, the fill uses a molybdenum oxyhalide precursor, such as MoO₂Cl₂. In some embodiments, the fill uses a molybdenum halide precursor, such as MoCl₅.

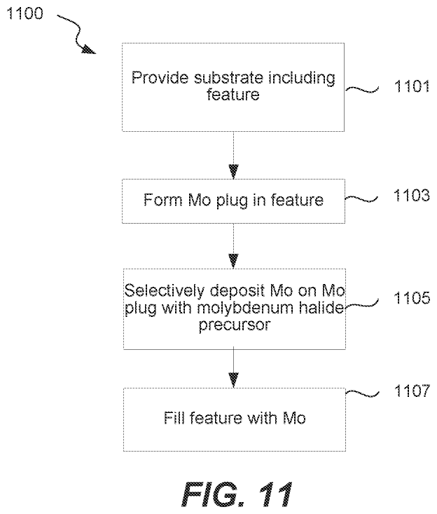

FIG. 11 is a process flow diagram illustrating a method to fill a feature having no metal surface with molybdenum film. Method 1100 begins with providing a substrate with no metal surface in operation 1101. The substrate may be provided to a semiconductor processing tool.

The feature generally has an opening with two sidewall surfaces that meet at a bottom of the feature. The feature bottom may be referred to as a closed end. The two sidewall surfaces generally are sloped such that the feature is V-shaped. It may be formed in a dielectric layer as a trench or via and connects to an underlying layer Examples of dielectric materials that form the bottom and sidewall are given above.

In operation 1103, a molybdenum plug is formed in a bottom portion of the feature. As described above, the molybdenum plug may be formed by depositing a molybdenum-containing halide precursor and a reactant. The molybdenum-containing halide precursor may be a molybdenum chloride precursor, such as MoCl₅. H₂ may be used as a reactant using the methods described above. The molybdenum plug may form in the feature bottom when deposition occurs using (i) a high ratio of a molybdenum chloride precursor relative to a H₂ reactant, (ii) a relatively high process pressure during deposition, or (iii) a combination thereof. In some embodiments, the substrate temperature may be below 450° C. for the formation of the plug.

In operation 1105, an initial molybdenum layer is selectively deposited onto the molybdenum plug at the bottom portion of the feature. The process parameters are controlled such that the initial molybdenum layer is deposited on the molybdenum plug at the bottom of the feature. The initial molybdenum layer may be deposited by ALD, plasma enhanced ALD, CVD, or plasma enhanced CVD using a molybdenum-containing halide precursor and a reactant. The molybdenum-containing halide precursor may be a molybdenum chloride precursor, such as MoCl₅. The reactant may be, for example, H₂. Examples of additional precursors and reactants are listed above.

As discussed above in operation 603, for ALD, the temperature of the substrate and the pressure of a chamber may be controlled. These process parameters may be used to control selectivity such that the molybdenum initial layer is initially deposited on the metal nitride surfaces on the bottom portion of the feature. In some embodiments, the substrate may be heated between 300° C. and 500° C., e.g., between 350° C. and 450° C. In some embodiments, the chamber may be pressurized to at least 10 Torr, e.g., to at least 30 Torr, or to at least 50 Torr.

After the initial molybdenum layer is deposited on the molybdenum plug, the feature is filled with molybdenum in operation 1107. The molybdenum fill is deposited on the initial molybdenum layer deposited in the previous operation. The fill may be done using the same molybdenum halide precursor used in the previous operation or may be filled using a molybdenum oxyhalide precursor in operation. The precursor may be deposited with a reactant such as H₂. The feature may be filled using ALD, plasma enhanced ALD, chemical vapor deposition (CVD), or plasma enhanced CVD.

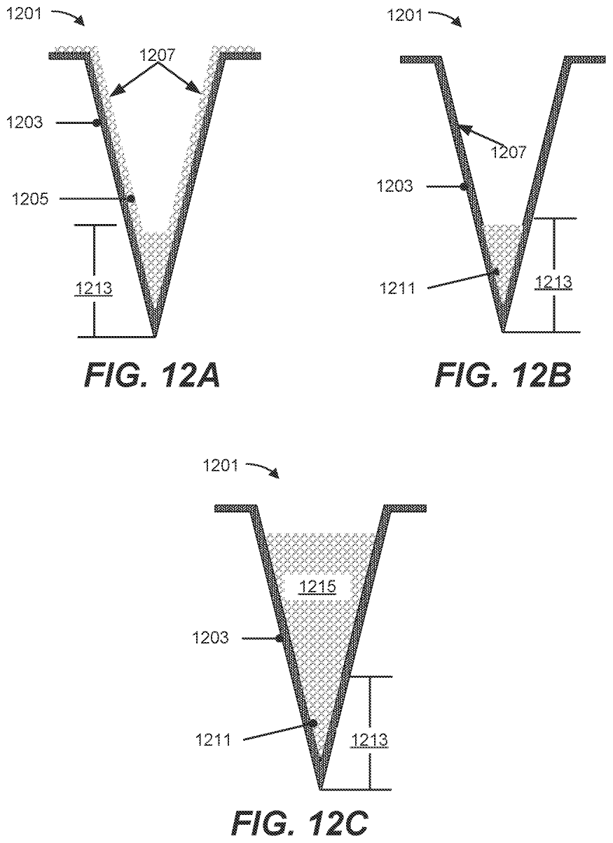

In some embodiments, a feature is filled using a molybdenum plug without a metal nitride layer. FIGS. 12A-12C show schematic examples of such a process. FIG. 12A shows a feature 1201 formed in a dielectric material 1203. The feature 1201 has a metal layer 1205 conformally deposited into the feature 1201. The feature 1201 also has a metal plug 1211. The metal, for example, may be Mo. The metal layer forms the two sidewall surfaces 1207. The feature 1201 is a V-shaped trench and has the sidewall surfaces 1207 converge at a bottom portion 1213 of the feature.

FIG. 12B shows the feature 1201 after undergoing etch operation. The feature undergoes an etch using a molybdenum-containing precursor. Examples include MoCl₅ and MoOCl₄. The etch removes a top portion of the metal layer 1205 so that the metal layer 1205 remains in the bottom portion 1213 of the feature 1201. After the etch, each of the sidewall surfaces 1207 has the dielectric material 1203 on the top portion of each of the sidewall surfaces. The metal plug 1211 remains in the feature. In some embodiments, the metal layer 1205 may be on a lower portion of the sidewall surfaces 1207.

FIG. 12C shows the feature 1201 after the feature is filled with Mo 1215. The initial Mo film is selectively deposited on the metal plug 1211. The Mo fill is deposited on the metal plug 1211 shown in FIG. 12B and grows up from the bottom portion 1213 of the feature until the feature is filled with Mo. The feature may be filled using ALD, plasma enhanced ALD, CVD, or plasma enhanced CVD. In some embodiments, the fill uses a molybdenum oxyhalide precursor, such as MoO₂Cl₂. In some embodiments, the fill uses a molybdenum halide precursor, such as MoCl₅.

In some embodiments, one or more of the following techniques may be used to reduce resistivity. A first technique is to use high flow rates for flowing gas into the chamber. A high flow rate may be about 5 slm to about 60 slm, e.g., between about 10 slm and 50 slm. In one example, the high flow rate may be used to flow H₂ gas into the chamber. In another example, the high flow rate may be used to flow a purge gas, such as Ar into the chamber.

A second technique is to use multiple H₂ pulses as a reactant. In deposition of film, after a precursor is flown into a chamber, H₂ may be used as a reactant. In some embodiments, multiple pulses of the H₂ gas may be used to react with a precursor. For example, a precursor gas is flowed into the chamber followed by two or more pulses of the H₂ reactant. In some embodiments, H₂ may be pulsed sequentially. In some embodiments, the sequence may have a H₂ gas flowed into the chamber, following a purge operation, followed by a second flow of H₂ gas into the chamber. In some embodiments, the H₂ gas flow, purge operation sequence may be continued for two or more times.

A third technique is to use charge volumes. Charge volumes may be used to increase the mass flow of the gas into the chamber. In some embodiments, multiple charge volumes may be used. By using multiple charge volumes, the mass flow of gas may increase as it enters into the chamber. In some embodiments, the multiple charge volumes may be used to sustain a higher mass flow rate into the chamber. In some embodiments, the charge volume may be used to flow the reactant, such as H₂ into the chamber. In some embodiments, the charge volume may be used to flow a purge gas. By using a charge volume to flow purge gas into the chamber, the chamber may be purged more quickly.

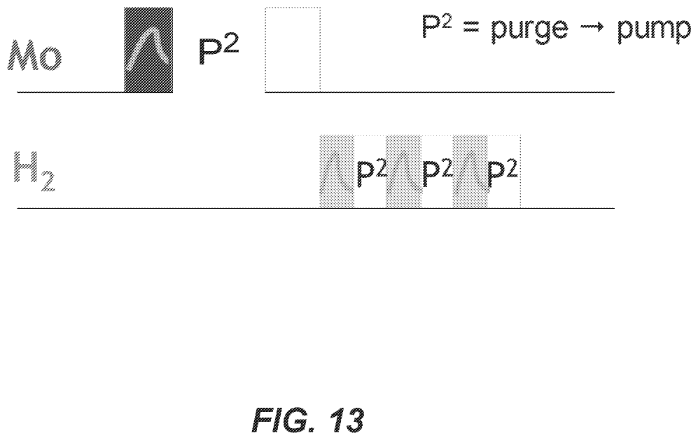

Shown in FIG. 13 is an example sequence that may be used to reduce the resistivity. In the sequence shown, a molybdenum-containing precursor is first flowed into the chamber. Examples of molybdenum-containing precursor are given above. Following the flow of the molybdenum-containing precursor is a purge operation. Following the purge, the pressure within the chamber is pumped down to a lower pressure. After the chamber pressure is pumped down, hydrogen is flowed into the chamber. The hydrogen is followed up by a purge operation and then chamber pressure pump down. As described above, the chamber pressure pump down lowers the chamber pressure. The mini-cycle of flowing hydrogen, followed by a purge operation and chamber pressure pump down may be repeated multiple times. In some embodiments, the mini-cycle may be cycled two or more times. In the sequence shown in FIG. 13, the mini-cycle of flowing hydrogen, followed by a purge operation and chamber pressure pump down is cycled three times.

In some embodiments, multiple charge volumes may be used for each purge operation. This is described in WO 2020/214732, incorporated by reference herein.

In some embodiments, one or more of the following techniques may be used to reduce grain boundaries. In a first technique, an inhibitor may be used on sidewalls of a feature. During deposition of molybdenum into the feature, an inhibitor may be used on the sidewalls to slow down or stop the growth of molybdenum on the sidewalls. A second technique is to etch or remove any Mo nuclei on the sidewalls of a feature. For example, during an etch operation as described above, MoCl₅ may be used to etch Mo nuclei on the sidewalls of the feature. In another example, molybdenum oxytetrachloride (MoOCl₄) may be used to etch Mo nuclei on the sidewalls. An example process may include a deposition of molybdenum into a feature. In the initial deposition of molybdenum, molybdenum nuclei may be deposited onto sidewalls of the feature. The deposition may be followed by an etch operation. An example etch operation may use MoCl₅ to etch. The etch may etch part of the Mo deposited into the feature include any Mo nuclei deposited onto the sidewalls. The etch may be followed by a deposition. The deposition may include depositing Mo. The deposition may be a bottom-up fill, depositing molybdenum onto molybdenum in the feature not etched away in the previous operation

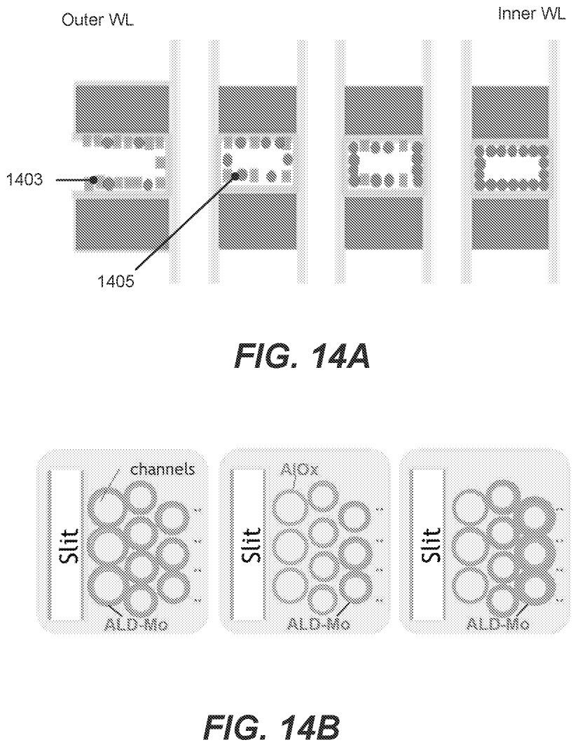

In 3D NAND structures, treatment of lateral features, such as wordlines, may be used to improve fill within the structures. Treatment may include nucleation inhibition, etching, or a combination thereof. Nucleation inhibition inhibits subsequent molybdenum nucleation at the treated surfaces. It can involve one or more of: deposition of an inhibition film, reaction of treatment species with the Mo film to form a compound film (e.g., Mo₂N), and adsorption of inhibition species. During a subsequent deposition operation, there is a nucleation delay on the inhibited portions of the underlying film relative to the non- or lesser-inhibited portions. As shown in FIG. 14A, an inhibitor non-conformally treats the feature. A higher amount of the inhibitor 1403 is towards the exterior of a feature and reduces as you move toward the interior of the feature. Higher amounts of untreated Mo film 1405 are on the interior of the feature. In the example shown, the Mo film 1405 may be deposited in the interior part of the feature. In a subsequent deposition, deposited Mo may be deposited on Mo within the feature while the inhibitor reduces or delays growth of the Mo. Examples of inhibitors include ammonia (NH₃), oxygen (O₂), nitrogen (N₂), H₂, methane (CH₄), hydrazine (N₂H₄), nitrogen trifluoride (NF₃), SiH₄, B₂H₆ and derivatives thereof, with or without plasma

Etch removes deposited film at the treated surfaces. This can involve reacting an etchant species with the molybdenum film to form a gaseous byproduct that is then removed. Other methods of etching, including atomic layer etching, may be performed. The etch operation may be a plasma or a non-plasma operation. If a non-plasma operation, it may be purely thermal or activated by some other energy such as UV.

Nitrogen acts as inhibition species and halogen (e.g., fluorine and chlorine) species act as etchants. To perform a purely inhibition treatment, one example includes treating the feature with a nitrogen-containing chemistry that does not contain halogens. To perform a purely etch treatment, treatment includes exposing the Mo film to a halogen-containing chemistry that does not contain nitrogen. Other inhibition chemistries (e.g., oxygen-containing chemistries) may be used in some embodiments. Exposing the film to both a nitrogen-containing and halogen-containing chemistry (e.g., nitrogen trifluoride (NF₃) or ammonia/fluorine (NH₃/F₂)) can both inhibit and etch.

FIG. 14B shows a feature after a deposition, etch, deposition sequence. A conformal ALD process may be used to deposit Mo into the features. As shown, Mo is deposited conformally around each of the features, evenly from the exterior (slit side) to the interior (non-slit side). Following the deposition, an etch operation may be performed. The etch may etch non-conformally such that the etch removes more of the Mo film on the exterior part of the wordline. In the exterior portion of the wordline, the oxide of the feature may be exposed. The interior portion of the wordline may be etched less such that Mo may remain on the interior features. A second deposition operation may performed after the etch operation shown. The deposition may be selective to the Mo film remaining on the film. Thus, the film deposited in the subsequent deposition may be deposited selective to the inner portion of the wordline. As Mo starts to grow, the deposition may become conformal. As shown, after the subsequent deposition, the Mo film may be thicker on the inner portion of the feature compared to the outer portion of the feature.

1. A method, comprising:
(a) providing a substrate comprising a feature comprising an opening and sidewalls, wherein a metal nitride layer lines the sidewalls of the feature;
(b) at least partially etching the metal nitride layer along the sidewalls of the feature using a molybdenum-containing halide compound to leave a first portion of the metal nitride layer in the feature; and
(c) after at least partially etching the metal nitride layer, selectively depositing molybdenum on the first portion of the metal nitride layer in the feature by reacting the molybdenum-containing halide compound with a first reactant.

2. The method of claim 1, wherein (b) comprises removing metal nitride from a portion of the sidewalls to expose the portion of the sidewalls of the feature.

3. The method of claim 1, wherein the feature has a feature bottom, and further comprising (d) after (c), at least partially etching the first portion of the metal nitride layer and molybdenum using the molybdenum-containing halide compound to leave a second portion of the metal nitride layer and remaining molybdenum on the feature bottom.

4. The method of claim 1, further comprising (e) filling the feature with molybdenum.

5. The method of claim 1, wherein the molybdenum-containing halide compound is a molybdenum chloride compound.

6. The method of claim 1, wherein the molybdenum-containing halide compound is molybdenum pentachloride.

7. The method of claim 4, wherein (e) comprises reacting a second molybdenum-containing halide compound with a second reactant.

8. The method of claim 4, wherein (e) comprises reacting a molybdenum-containing oxyhalide precursor with a second reactant.

9. The method of claim 1, wherein the metal nitride layer conformally lines the feature.

10. The method of claim 1, wherein (b) further comprises reacting the molybdenum-containing halide compound with the first reactant to deposit molybdenum in the feature during the etch.

11. The method of claim 1, wherein the first reactant is a hydrogen-containing reactant.

12. The method of claim 1, wherein the first reactant is hydrogen (H₂).

13. The method of claim 1, wherein:
(b) is performed at a first substrate temperature;
(c) is performed at a second substrate temperature; and
the second substrate temperature is higher than the first substrate temperature.

14. A method, comprising:
(a) providing a substrate comprising a feature comprising an opening, a closed end, and sidewalls;
(b) forming a molybdenum plug on the closed end of the feature by reacting a molybdenum-containing halide compound with a first reactant; and
(c) selectively depositing molybdenum on the molybdenum plug by reacting the molybdenum-containing halide compound with the first reactant.

15. The method of claim 14, wherein the sidewalls are sloped and meet at the closed end of the feature.

16. The method of claim 14, further comprising (d) after (c), filling the feature with molybdenum.

17. The method of claim 16, wherein (d) comprises reacting a second molybdenum-containing halide compound with a second reactant.

18. The method of claim 16, wherein (d) comprises reacting a molybdenum-containing oxyhalide compound with a second reactant.

19. The method of claim 14, wherein the molybdenum-containing halide compound is a molybdenum chloride compound.

20.-23. (canceled)

21. A method, comprising:
(a) providing a substrate comprising a feature with a metal nitride plug; and
(b) selectively depositing molybdenum on the metal nitride plug in the feature by reacting a molybdenum-containing halide compound and a first reactant.

22.-31. (canceled)
